(19) United States
(12) Patent Application Publication
(10) Pub. No.: US 2025/0068079 A1
(43) Pub. Date: Feb. 27, 2025

(54) BIO-BASED SOLVENTS FOR NEGATIVE TONE DEVELOPMENT

(71) Applicant: Phillip Dene Hustad, St. Paul, MN (US)

(72) Inventor: Phillip Dene Hustad, St. Paul, MN (US)

(21) Appl. No.: 18/905,832

(22) Filed: Oct. 3, 2024

Related U.S. Application Data
(63) Continuation of application No. PCT/US2023/080051, filed on Nov. 16, 2023.
(60) Provisional application No. 63/426,285, filed on Nov. 17, 2022.

(51) Int. Cl. G03F 7/32; G03F 7/20; G03F 7/40

(52) U.S. Cl. CPC G03F 7/325; G03F 7/2004; G03F 7/40

(57) ABSTRACT

Non-aqueous bio-based organic solvents for use in lithographic processes are described, along methods of making and using such solvents. More specifically, the disclosure contemplates non-aqueous developer and rinsing compositions that are synthesized from biological or renewable sources and further, employing such bio-based developers to produce high resolution negative-tone images using a photoresist, and utilizing said bio-based rinsing agents for the negative tone development patterning processes.

### CLAIM OF PRIORITY

This patent application is a CONTINUATION under 35 U.S.C. 111(a) of PCT Application Serial No. PCT/US2023/080051, filed Nov. 16, 2023, which application claims the benefit of priority to U.S. Application Ser. No. 63/426,285, filed Nov. 17, 2022, which are incorporated by reference herein in their entireties.

### FIELD OF THE DISCLOSURE

The field of the disclosure comprises bio-based compositions for negative tone development and methods of using such bio-based compositions. More particularly, the disclosure contemplates non-aqueous developer and rinsing compositions that are synthesized from biological or renewable sources and further, employing such bio-based developers to produce high resolution negative-tone images using a photoresist and/or utilizing said bio-based rinsing agents for the negative tone development patterning process.

### BACKGROUND OF THE DISCLOSURE

The realization of advanced lithographic technology beyond the 14 nm node requires the implementation of patterning materials and processes with ultimate performance to cope with intrinsically contrast-limited exposure tools. The reduction in imaging wavelength from the long-standing 193 nm ArF Lithography (DUV) to the expected 13.5 nm Extreme Ultraviolet Lithography (EUV) will improve the resolving power of ultimate optical systems used by the semiconductor industry and is expected to enable the extension of Moore's Law to the 10 nm node and beyond.

The optical resolving power of ArF and EUV scanners can only be realized as a material pattern formed on a semiconductor substrate if the spatial resolution of the imaging material is commensurate to the quality of the delivered aerial image. At the same time, the imaging layer is required to carry acceptable sensitivity to the imaging wavelength and provide low line-width roughness (LWR), good adhesion to the underlying substrate and large post apply bake (PAB) and post exposure bake (PEB) latitude. Chemically-amplified resists have become the workhorse of the lithographic industry due to the ability to satisfy the aforementioned requirements in a suitable manner across multiple technology nodes.

Chemically-amplified (CA) resists are incorporated into lithographic processes through two different types of development. Positive tone resist imaging and development is a process wherein the exposed regions of a photoresist are removed by an aqueous basic developer (tetraalkylammonium hydroxide (TMAH)) after a PEB step, while the unexposed regions remain insoluble. This is referred to as positive-tone development (PTD) and is described in detail in 4 J. Photopolym Sci. Technol. 299 (1991).

Alternatively, negative tone resists behave in the opposite manner. When exposed to the UV light, the negative resists become crosslinked/polymerized, and more difficult to dissolve in a developer. Therefore, the negative resist remains on the surface of the substrate where it is exposed, and the developer solution removes only the unexposed areas. Masks used for negative photoresists, therefore, contain the inverse or photographic “negative” of the pattern to be transferred. One way to reverse the tone of a chemically amplified resist originally designed to be developed in the positive tone with aqueous base developer is to utilize an organic developer that removes the unexposed portion of the resist film, while the exposed regions remain unaffected. This process is known as negative-tone development (NTD) and has found extensive applications in the area of 193 nm double patterning using bright field masks, particularly in the case of small feature openings such as contact hole and trench patterning. As used herein, NTD refers to the use of organic solvents as developers to produce negative-tone images.

There are a number of challenges, however, with the industrial application of NTD. Due to toxicological, environmental, and especially flammability issues, there are a limited number of organic solvents that are compatible with practical industrial-scale semiconductor manufacturing. Common solvents used in track processes include n-butyl acetate (NBA), 2-heptanone, propylene glycol methyl ether acetate (PGMEA), propylene glycol methyl ether (PGME), methyl isobutyl carbinol (MIBC), and ethyl lactate.

While the current solvents used in NTD processes are commercially viable, they are still not ideal and present additional problems for the semiconductor industry. These solvents are all manufactured from petrochemically-derived raw materials. The integrated circuit industry is particularly interested in finding alternatives to petrochemically-derived solvents, because of the environmental costs associated with these products, as well as their contribution to greenhouse emissions from their high petroleum derived carbon content. Furthermore, petrochemicals take hundreds of thousands of years to form naturally, making petrochemically-derived products non-renewable, which means they cannot be re-made, re-grown, or regenerated at a rate comparative to its consumption.

Thus, there exists an unmet need for solvents that are usable on fabrication development tracks that are derived from renewable resources that share similar properties as petroleum-derived solvents. Further, because of the large investment costs associated with semiconductor development and fabrication, it would also be advantageous if the solvents derived from renewable resources can be processed through existing solvent manufacturing facilities.

### SUMMARY OF THE INVENTION

The present disclosure comprises compositions, processes and products that address the foregoing needs, and provides environmental improvements, such as lower greenhouse gas emissions, to track based processes through the synthesis of bio-based organic solvents and utilization of such solvents.

A first aspect of the disclosure comprises a composition comprising an organic developer comprising at least 25 wt % bio-based n-butyl acetate wherein the bio-based n-butyl acetate comprises an amount of carbon-14 sufficient to produce a decay of at least 0.1 dpm/gC (disintegrations per minute per gram carbon); wherein the organic developer comprises 5 ppb or less of metal element concentration of each of Na, K, Ca, Fe, Cu, Mg, Mn, Li, Al, Cr, Ni, and Zn. In some embodiments, the first aspect further comprises 1 ppb or less of an alkane or alkene having a carbon number of 22 or less and Zn; and 3 wt % or less bio-based n-butanol.

In some embodiments of the first aspect, the organic developer comprises one or more of 0.5 ppb or less of an alkane or alkene having a carbon number of 22 or less; 3 ppb or less of metal element concentration of each of Na, K, Ca, Fe, Cu, Mg, Mn, Li, Al, Cr, Ni, and Zn; and 1 wt % or less bio-based n-butanol, 0.1 wt % or less n-hexadecane, 0.1 wt % or less isopropanol, and 0.1 wt % or less ethyl acetate.

In some embodiments of the first aspect, the organic developer comprises one or more of: 0.3 ppb or less of an alkane or alkene having a carbon number of 22 or less; 1 ppb or less of metal element concentration of each of Na, K, Ca, Fe, Cu, Mg, Mn, Li, Al, Cr, Ni, and Zn; and 1 wt % or less in total other bio-based solvents.

In some embodiments of the first aspect, the organic developer comprises at least 90 wt % bio-based n-butyl acetate. The composition of claim 1, wherein the organic developer comprises at least 95 wt % bio-based n-butyl acetate. The composition of claim 1, wherein the organic developer comprises 0.001 wt % to 5 wt % surfactant. The composition of claim 6, wherein the surfactant comprises an ionic or nonionic fluorine-based or silicon-based surfactant.

A second aspect of the disclosure comprises a pattern forming method comprising: a) providing a semiconductor substrate; b) forming a resist film comprising coating the semiconductor substrate with a resist composition having a solubility, wherein the solubility of the resist composition in an organic developer decreases upon irradiation with actinic rays or radiation; c) exposing the resist film with actinic rays or electromagnetic radiation; and d) developing the resist film with the organic developer, the organic developer comprising at least 25 wt % bio-based n-butyl acetate wherein the bio-based n-butyl acetate comprises an amount of carbon-14 sufficient to produce a decay of at least 0.1 dpm/gC (disintegrations per minute per gram carbon).

In some embodiments of the second aspect, the solubility of the resist composition, after exposing the resist film with actinic rays or electromagnetic radiation, in the organic developer is 25 or less as described by a ratio mₛᵥ/mₛᵤ, wherein mₛᵥ is a mass of the solvent of the organic developer required to dissolve one unit of mass of resist composition, mₛᵤ.

The second aspect may further comprise forming an integrated circuit on the semiconductor substrate. In some embodiments, the integrated circuit has a transistor density of 3×10⁷ transistors/mm².

In some embodiments of the second aspect, the organic developer comprises 5 ppb or less of metal element concentration of each of Na, K, Ca, Fe, Cu, Mg, Mn, Li, Al, Cr, Ni, and Zn. In some embodiments, the second aspect further comprises 1 ppb or less of an alkane or alkene having a carbon number of 22 or less and 3 wt % or less bio-based n-butanol.

In some embodiments of the second aspect, the organic developer comprises one or more of: 0.5 ppb or less of an alkane or alkene having a carbon number of 22 or less; 3 ppb or less of metal element concentration of each of Na, K, Ca, Fe, Cu, Mg, Mn, Li, Al, Cr, Ni, and Zn; and 1 wt % or less bio-based n-butanol, 0.1 wt % or less n-hexadecane, 0.1 wt % or less isopropanol, and 0.1 wt % or less ethyl acetate.

In some embodiments of the second aspect, the organic developer comprises one or more of: 0.3 ppb or less of an alkane or alkene having a carbon number of 22 or less; 2 ppb or less of metal element concentration of each of Na, K, Ca, Fe, Cu, Mg, Mn, Li, Al, Cr, Ni, and Zn; and 1 wt % or less in total other bio-based solvents.

In some embodiments of the second aspect, the organic developer comprises at least 90 wt % bio-based n-butyl acetate. In some embodiments the organic developer comprises at least 95 wt % bio-based n-butyl acetate.

In some embodiments of the second aspect, the organic developer further comprises 0.001 wt % to 5 wt % surfactant. In some embodiments the surfactant comprises an ionic or nonionic fluorine-based or silicon-based surfactant.

In some embodiments of the second aspect, the method further comprises a step of rinsing the semiconductor substrate with a rinse solution after the developing step, wherein the rinse solution comprises at least one bio-based organic solvent that comprises an amount of carbon-14 (C-14) sufficient to produce a decay of at least 0.1 dpm/gC (disintegrations per minute per gram carbon) and 5 ppb or less of a metal element concentration of each of Na, K, Ca, Fe, Cu, Mg, Mn, Li, Al, Cr, Ni, and, Zn. In some embodiments of the second aspect, the bio-based organic solvent is selected from the group consisting of one or more of a hydrocarbon-based solvent, a ketone-based solvent, an ester-based solvent, an alcohol-based solvent, an amide-based solvent, an ether-based solvent, and combinations thereof. In some embodiments of the second aspect, the rinse solution the bio-based organic solvent is selected from the group consisting of one or more of 1-hexanol, methyl isobutyl carbinol, 2-hexanol, 1-heptanol, 2-heptanol, and combinations thereof.

A third aspect of the disclosure comprises a rinse composition comprising: at least 25 wt % of a bio-based organic rinse solvent selected from the group consisting of a hydrocarbon-based solvent, a ketone-based solvent, an ester-based solvent, an alcohol-based solvent, an amide-based solvent, an ether-based solvent, and combinations thereof, wherein the bio-based rinse organic solvent comprises an amount of carbon-14 sufficient to produce a decay of at least 0.1 dpm/gC (disintegrations per minute per gram carbon); and wherein the rinse composition comprises 5 ppb or less of metal element concentration of each of Na, K, Ca, Fe, Cu, Mg, Mn, Li, Al, Cr, Ni, and Zn. In some embodiments, the bio-based organic rinse solvent is selected from the group consisting of one or more of 1-hexanol, methyl isobutyl carbinol, 2-hexanol, 1-heptanol, 2-heptanol, and combinations thereof. In some embodiments, the rinse composition further comprises: 1 ppb or less of an alkane or alkene having a carbon number of 22 or less or 3 wt % or less bio-based n-butanol. In some embodiments the organic developer comprises at least 90 wt % of one or more of bio-based 1-hexanol, methyl isobutyl carbinol, 2-hexanol, 1-heptanol and 2-heptanol. In some embodiments the organic developer comprises at least 95 wt % of one or more of bio-based 1-hexanol, methyl isobutyl carbinol, 2-hexanol, 1-heptanol and 2-heptanol.

In some embodiments of the fourth aspect, the rinse composition comprises one or more of: 0.5 ppb or less of an alkane or alkene having a carbon number of 22 or less; 3 ppb or less of metal element concentration of each of Na, K, Ca, Fe, Cu, Mg, Mn, Li, Al, Cr, Ni, and Zn; and 1 wt % or less bio-based n-butanol, 0.1 wt % or less n-hexadecane, 0.1 wt % or less isopropanol, and 0.1 wt % or less ethyl acetate.

In some embodiments of the fourth aspect, the rinse composition comprises one or more of: 0.3 ppb or less of an alkane or alkene having a carbon number of 22 or less; 2 ppb or less of metal element concentration of each of Na, K, Ca, Fe, Cu, Mg, Mn, Li, Al, Cr, Ni, and Zn; and 1 wt % or less in total other bio-based solvents.

In accordance with a further aspect of the disclosure, provided are electronic devices formed by the methods described herein.

### BRIEF DESCRIPTION OF THE DRAWINGS

The present disclosure will be described with reference to the following drawing, in which like reference numerals denote like features, and in which:

FIG. 1A-1E illustrates an exemplary process flow for forming a pattern in accordance with the disclosure.

Referring to the drawings in general, it will be understood that the illustrations are for the purpose of describing particular embodiments and are not intended to limit the disclosure or appended claims thereto. The drawings are not necessarily to scale, and certain features and certain views of the drawings may be shown exaggerated in scale or in schematic in the interest of clarity and conciseness.

### DETAILED DESCRIPTION OF THE INVENTION

The following description sets forth exemplary embodiments of the present technology. It should be recognized, however, that such description is not intended as a limitation on the scope of the present disclosure but is instead provided as a description of exemplary embodiments.

Unless defined otherwise, all technical and scientific terms used herein have the same meaning as is commonly understood by one of ordinary skill in the art. As used herein, the below terms have the following meanings unless specified otherwise. Any methods, devices, and materials similar or equivalent to those described herein can be used in the practice of the compositions and methods described herein. The following definitions are provided to facilitate understanding of certain terms used frequently herein and are not meant to limit the scope of the present disclosure. All references referred to herein are incorporated by reference in their entirety.

The term “comprise” and variations thereof, such as, “comprises” and “comprising” are to be construed in an open, inclusive sense, that is, as “including, but not limited to.” The term “consisting essentially of” is construed to mean that the composition/process (a) necessarily includes the listed ingredients/steps and (b) is open to unlisted ingredients/steps that do not materially affect the basic and novel properties of the composition/process. The term “consisting of” is closed-ended and excludes any element, step, or ingredient not specifically mentioned after that phrase. Further, the singular forms “a,” “an,” and “the” include plural references unless the context clearly dictates otherwise. Thus, references to “the embodiment” include a plurality of such embodiments.

In some embodiments, there are a number of possible alternatives that can be chosen. In such cases, the terminology “at least one of [A], [B] and [C]” or “one or more of [A], [B] and [C]” is used to mean “either [A], [B], [C] or any possible combination of [A], [B] and [C],” such as [A] and [B] or [A], [B], and [C]. In cases where “[A] or [B]” is used, it should be interpreted as “either or both” and not as alternatives—e.g., “[A] or [B]” is equivalent to “[A] or [B] or the combination [A] and [B].” For sake of clarity, the disclosure may include “and combinations thereof” to further clarify that in cases where alternatives are listed, the list further comprises combinations thereof.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue. For example, reference to “about” a value or parameter herein includes (and describes) embodiments that are directed to that value or parameter per se. In certain embodiments, the term “about” includes the indicated amount±10%. In other embodiments, the term “about” includes the indicated amount±5%. In certain other embodiments, the term “about” includes the indicated amount±1%. Also, to the term “about X” includes description of “X.”

“Ring,” “cycle,” “cyclic,” “alicyclic,” or like terms generally refer to at least one continuous closed loop, ring, or chain of atoms and can include, for example, saturated alicyclics, unsaturated alicyclics, aromatics, hetero-aromatics (heteroaryl), and like cyclic classifications, or combinations thereof, including monocyclic, bicyclic, tricyclic, and like conventional designations.

“Alkyl” includes linear alkyls and branched alkyls. “Substituted alkyl” or “optionally substituted alkyl” refers to an alkyl substituent, which can include, for example, a linear alkyl or a branched alkyl having from 1 to 4 optional substituents selected from, for example, hydroxyl (—OH), halogen, amino (—NH₂ or —NR₂), nitro (—NO₂), acyl (—C(═O)R), alkylsulfonyl (—S(═O)₂R), alkoxy (—OR), (C₃₋₁₀)cycloalkyl, and like substituents, where R is a hydrocarbyl, aryl, het, or like moieties, such as a monovalent alkyl or a divalent alkylene having from 1 to about 10 carbon atoms. For example, a hydroxy substituted alkyl, can be a 2-hydroxy substituted propylene of the formula —CH₂—CH(OH)—CH₂—, an alkoxy substituted alkyl, can be a 2-methoxy substituted ethyl of the formula —CH₂—CH₂—O—CH₃, an amino substituted alkyl, or can be a 1-dialkylamino substituted ethyl of the formula —CH(NR₂)—CH₃.

“Alkane” includes unsubstituted linear, cyclic, and branched saturated alkanes.

“Alkene” includes unsubstituted linear, cyclic, and branched saturated alkenes having at least one carbon-carbon double bond.

“Cycloalkyl” includes cyclic alkyls. “Substituted cycloalkyl” or “optionally substituted cycloalkyls” refers to a cycloalkyl substituent having from 1 to 4 optional substituents selected from, for example, alkyl, alkenyl, alkynyl, hydroxyl (—OH), halogen, amino (—NH₂ or —NR₂), nitro (—NO₂), acyl (—C(═O)R), alkylsulfonyl (—S(═O)₂R), alkoxy (—OR), and like substituents.

“Alkoxyl” includes an alkyl group bound to the base structure via an oxygen atom, —O—Ra, wherein Ra can include optionally substituted linear alkyls or branched alkyls as described above.

“Alkoxylcarbonyl” includes an alkyl group bound the base structure via an oxygen, with a carbonyl group adjacent the oxygen, —O—C(═O)—R^{b}, wherein R^{b} can include optionally substituted linear alkyls or branched alkyls as described above.

“Carboxyl” means a moiety composed of carbon bonded to both an oxygen and a hydroxyl group, —C(═O)—O—H.

“Hydroxyl” means an —O—H chemical moiety.

“Aryl” includes a mono- or divalent-phenyl radical or an ortho-fused bicyclic carbocyclic radical having about nine to twenty ring atoms in which at least one ring is aromatic. Aryl (Ar) can include substituted aryls, such as a phenyl radical having from 1 to 5 substituents, for example, alkyl, alkoxy, halo, and like substituents.

“Het” includes a four-(4), five-(5), six-(6), or seven-(7) membered saturated or unsaturated heterocyclic ring having 1, 2, 3, or 4 heteroatoms selected from the group consisting of oxy, thio, sulfinyl, sulfonyl, selenium, tellurium, and nitrogen, which ring is optionally fused to a benzene ring. Het also includes “heteroaryl,” which encompasses a radical attached via a ring carbon of a monocyclic aromatic ring containing five or six ring atoms consisting of carbon and 1, 2, 3, or 4 heteroatoms each selected from the group consisting of non-peroxide oxy, thio, and N(X) wherein X is absent or is H, O, (C₁₋₄)alkyl, phenyl, or benzyl, and a radical of an ortho-fused bicyclic heterocycle of about eight to ten ring atoms derived therefrom, particularly a benzo-derivative or one derived by fusing a propylene, trimethylene, or tetramethylene diradical thereto.

Alkyl, alkoxy, etc., include both straight and branched groups; but reference to an individual radical such as “propyl” embraces only the straight chain radical, a branched chain isomer such as “isopropyl” being specifically referred to.

The carbon atom content of various hydrocarbon-containing (i.e., hydrocarbyl) moieties can alternatively be indicated by a prefix designating a lower and upper number of carbon atoms in the moiety, i.e., the prefix Cᵢ₋ⱼ indicates a moiety of the integer “i” to the integer “j” carbon atoms, inclusive. Thus, for example, (C₁-C₈)alkyl or C₁₋₈alkyl refers to an alkyl of one to eight carbon atoms, inclusive, and hydrocarbyloxy such as (C₁-C₈)alkoxy or C₁₋₈alkoxy refers to an alkoxy radical (—OR) having an alkyl group of one to eight carbon atoms, inclusive. Specifically, a C₁₋₈alkyl can be, for example, methyl, ethyl, propyl, isopropyl, butyl, iso-butyl, sec-butyl, tert-butyl, pentyl, 3-pentyl, hexyl, heptyl, or octyl; (C₃₋₁₂)cycloalkyl can be cyclopropyl, cyclobutyl, cyclopentyl, cyclohexyl, cycloheptyl, cyclooctyl, including bicyclic, tricyclic, or multi-cyclic substituents, and like substituents.

A specific “C_{x-y}” as used herein for the groups described, for example, (C₁₀₋₂₀)alkyl, may be used to limit the group and includes all intermediate chain lengths and values. C₁₋₈alkoxy can be, for example, methoxy, ethoxy, propoxy, isopropoxy, butoxy, iso-butoxy, sec-butoxy, pentoxy, 3-pentoxy, hexyloxy, 1-methylhexyloxy, heptyloxy, octyloxy, and like substituents.

The present disclosure provides novel bio-based compounds for use in lithography and other patterning processes, along with methods of synthesizing such compounds and processes for using such compounds in lithographic processes. The term “bio-based,” as used in this application, indicates the inclusion of some component that derives from at least one bio-based material. For example, a “bio-based n-butyl acetate” solvent (“NBA”) would be NBA that is either partially or totally derived from at least one bio-based material. As used herein, “bio-based materials” refer to organic materials in which the carbon comes from non-fossil biological sources. Examples of bio-based materials include, but are not limited to, sugars, starches, corns, natural fibers, sugarcanes, beets, citrus fruits, woody plants, cellulosics, lignocelluosics, hemicelluloses, potatoes, plant oils, other polysaccharides such as pectin, chitin, levan, and pullulan, and a combination thereof. According to a particular embodiment, at least one bio-based material is selected from corn, sugarcane, beet, potato, starch, citrus fruit, woody plant, cellulosic lignin, plant oil, natural fiber, oily wood feedstock, and combinations thereof.

Fossil biological sources, or fossil fuels, as used herein, include hydrocarbon-containing materials, such as coal, crude oil, and natural gas, formed naturally in the earth's crust from the remains of dead plants and animals, as well as refined or synthesized materials stemming from such. The key differentiator of fossil biological sources from bio-based materials is that fossil biological sources stem from the anaerobic decomposition of buried dead organisms into high-carbon fossil fuels over millions of years.

Carbon-14 is a radioactive isotope of carbon that is formed in the upper layers of the troposphere and the stratosphere by thermal neutrons absorbed by nitrogen atoms. When cosmic rays enter the atmosphere, they undergo various transformations, including the production of neutrons. The resulting neutrons (1n) participate in the following n-p reaction:

$$\\ 14 / 7 N + neutron \to 14 / 6 C + proton$$

After production in the upper atmosphere, the carbon-14 atoms react rapidly to form mostly (about 93%) ¹⁴CO (carbon monoxide), which subsequently oxidizes at a slower rate to form ¹⁴CO₂, radioactive carbon dioxide. The gas mixes rapidly and becomes evenly distributed throughout the atmosphere (the mixing timescale in the order of weeks) and is incorporated into biological organisms.

Carbon-14 (C-14) has a half-life of about 5,700 years, making it useful as a detector for determining the source of carbon in synthetic materials. C-14's relatively short half-life means that it can be found in bio-based materials, but not in fossil biological sources. A sample of the compound that is bio-based compound will possess a measurable amount of C-14 incorporated into the compound. A sample of the compound prepared from petroleum-based materials will possess essentially no C-14 or negligible to undetectable levels of C-14. As such, a key distinguishing factor of the novel bio-based solvents described herein is that they comprise C-14 in detectable amounts that allow for distinguishing them from traditional, fossil-based solvents.

Detection of the presence of C-14 in the compositions described herein can be done based on techniques known in the art. Without being limiting, examples of methods for determining C-14 presence and composition levels include use of accelerator mass spectrometry (AMS), liquid scintillation counting (LSC), or beta-ionization techniques (BI). In some embodiments, liquid scintillation is used as the standard method for measuring C-14 levels. Carbon percentage can be compared to total carbon in product or percentage as function of total mass of product. Specific examples of standards for measuring C-14 in commercial products are:
a. ASTM D6866, Standard Test Methods for Determining the Biobased Content of Solid, Liquid, and Gaseous Samples Using Radiocarbon Analysis, first published in 2004 and last updated as ASTM D6866-22 in March 2022, herein incorporated by reference, was developed in the United States as a standardized analytical method for determining the biobased content of solid, liquid, and gaseous samples using radiocarbon dating. It is one method to certify the biobased content of commercial products. A working standard of radiocarbon dating for industrial use was completed in 2004 and is now cited in U.S. Federal Law (7 CFR part 2902).
b. CEN/TS 16640:2014, Bio-based products—Determination of the bio-based carbon content of products using the radiocarbon method, is a European standard that provides technical specification for the determination of the bio-based carbon content in products, based on the 14C content measurement. It specifies three test methods to be used for the determination of the 14C content from which the bio-based carbon content is calculated: A) Liquid scintillation-counter method (LSC); B) Beta-ionization (BI); and C) Accelerator mass spectrometry (AMS). The bio-based carbon content is expressed by a fraction of sample mass, as a fraction of the total carbon content or as a fraction of the total organic carbon content. This calculation method is applicable to any product containing organic carbon, including biocomposites.
c. CSN EN 16785-1—Bio-based products—Bio-based content—Part 1: Determination of the bio-based content using the radiocarbon analysis and elemental analysis

Bio-based solvents described herein have non-zero or detectable amounts of C-14. Example quantitatively measured levels of C-14 in the compositions include:
a. a radioactive decay of at least 0.01, 0.1, 0.5, 1.0, 1.5, 2, 3, 4, 5, 6, 7, 8, 9, 10, 11, 12, 13, or 14 dpm/gC (disintegrations per minute per gram carbon) of carbon-14 (C-14). In some embodiments, the compositions described herein measure 0.1-14, 0.1-13, 0.1-12, 0.1-11, 0.1-10, 0.1-8, 0.1-6, 0.1-4, 0.1-2, 0.1-0.5, 0.5-14, 0.5-13, 0.5-12, 0.5-11, 0.5-10, 0.5-8, 0.5-6, 0.5-4, 0.5-2, 1-14, 1-13, 1-12, 1-11, 1-10, 1-8, 1-6, 1-4, 1-2, 2-14, 2-13, 2-12, 2-11, 2-10, 2-8, 2-6, 2-4, 4-14, 4-13, 4-12, 4-11, 4-10, 4-8, 4-6, 6-14, 6-13, 6-12, 6-11, 6-10, 6-8, 8-14, 8-13, 8-12, 8-11, 8-10, 10-14, 10-13, 10-12, 10-11, 11-14, 11-13, 11-12, 12-14, 12-13, or 13-14 dpm/gC;
b. measuring the ratio of ¹⁴C to ¹²C in a sample of the compound. A bio-based compound will comprise a ¹⁴C/¹²C ratio greater than zero. In some embodiments, the bio-based compound will have a ¹⁴C/¹²C ratio greater or equal to 1×10⁻³, 2.5×10⁻³, 5×10⁻³, 7.5×10⁻¹², 9×10⁻¹², 1×10⁻², 1.1×10⁻², 1.2×10⁻², 1.3×10⁻², 1.4×10⁻², 1.45×10⁻², 1.5×10⁻². In some embodiments, the bio-based compound will have a ¹⁴C/¹²C ratio from 7.5×10⁻³ to 1.5×10⁻¹², 1.2×10⁻² to 1.5×10⁻², 1.3×10⁻² to 1.5×10⁻², 1.4×10⁻² to 1.5×10⁻², or 1.45×10⁻² to 1.5×10⁻².
c. In some embodiments, the bio-based solvents described herein comprise a greater than 25, 50, 75, 100, 150, 175, 200, or 225 becquerels (Bq) of C-14 per kilogram (kg) of total carbon.

In some embodiments, there may be practical or economic reasons to use a solvent mixture or combination of solvents wherein at least some of the solvents are bio-based. In some embodiments, the bio-based solvent comprises greater than 5, 10, 15, 20, 25, 30, 35, 40, 45, 50, 60, 70, 80, 90, 95, 98, 99, 99.5, or 99.9% by weight of the overall solvent mixture. In some embodiments, the bio-based solvent comprises from 5-99%, 10-99%, 20-99%, 30-99%, 40-99%, 50-99%, 60-99%, 70-99%, 80-99%, 90-99%, 5-90%, 10-90%, 20-90%, 30-90%, 40-90%, 50-90%, 60-90%, 70-90%, 80-90%, 5-80%, 10-80%, 20-80%, 30-80%, 40-80%, 50-80%, 60-80%, 70-80%, 5-70%, 10-70%, 20-70%, 30-70%, 40-70%, 50-70%, 60-70%, 5-60%, 10-60%, 20-60%, 30-60%, 40-60%, 50-60%, 5-50%, 10-50%, 20-50%, 30-50%, 40-50%, 5-40%, 10-40%, 20-40%, 30-40%, 5-30%, 10-30%, 20-30%, 5-20%, 10-20%, or 5-10% by weight of the overall solvent mixture.

Bio-based content is determined based on the amount of bio-based carbon in the material or product as a percent of weight of the total organic carbon in the material or product. In embodiments where the solvent is a mixture or combination of solvents wherein at least some of the solvents are bio-based, the bio-based content of the solvent may be approximated by several methods. For example, measuring the specific activity in dpm/gC of the mixture and applying the following equation can provide an estimate the bio-based content:

$$\\ wt \% bio ‐ based = 100 * ( specific activity of mixture ) / ( specific activity of 100 \% bio ‐ based )$$

As the global inventory of natural C-14 is approximately 75 tons, the specific activity is >13.56 dpm/gC. The anticipated specific activity of a bio-based material can be approximated according to this value according to the following equation:

$$\\ specific activity of material X = ( weight fraction of carbon in material ) * 13.56 dpm / gC$$

For example, NBA has a carbon content of 0.621, so pure bio-based NBA has an anticipated specific activity of 8.4 dpm/gC. Accordingly, a mixture with greater than 50% by weight bio-based NBA is anticipated to have a specific activity of approximately 4.2 dpm/gC.

### Bio-Based Negative Developer

The bio-based negative developer is a bio-based organic solvent that dissolves a resist film that has been exposed to actinic rays or electromagnetic radiation as part of semiconductor pattern forming method. In a particular embodiment, the present disclosure is directed to use of n-butyl acetate (“NBA”), also known as butyl acetate, acetic acid n-butyl ester, butyl ethanoate, or butile, as a bio-based negative developer. Traditionally, NBA has been derived from fossil fuels. It is highly desirable to find a bio-based alternative that would meet the needs of the integrated circuit community while also providing a sustainable and renewable solvent that is environmentally friendly. However, as noted herein, development of bio-based solvents poses unique, non-obvious challenges that need to be overcome to make substitution of a bio-based solvent into the semiconductor space feasible. Processes for synthesizing bio-based solvents—for example, fermentation—lead to multiple side reactions creating alternative solvents such as isobutanol and iso-butylacetate, acetone, butanol, and ethanol (ABE) that are difficult to separate, as well as water and acetic acid, butyric acid, and higher alcohols along with impurities, such as metals and particulate matter.

To meet the stringent requirements of the semiconductor industry, a bio-based NBA negative developer needs to be of high to ultra-high purity. It is critical that the semiconductor wafer surface is not contaminated with any metallic impurities present in the NBA. In fact, micro-contamination accounts for over 50% of yield loss in IC manufacturing. Therefore, minimizing the metal impurity content of materials used in these processes is demanded as a matter of course. Solvents must be purified to extremely low-level metal content. The metal element concentration may be measured according to inductively coupled plasma mass spectrometry (e.g., an inductively coupled plasma mass spectrometer, Agilent 7500cs (ICP-MS equipment) manufactured by Agilent Technologies, Inc.). The bio-based NBA negative developer should comprise 5 parts per billion (ppb) or less of metal element concentration of each of Na, K, Ca, Fe, Cu, Mg, Mn, Li, Al, Cr, Ni, and Zn. In some embodiments, the metal element concentration of each of Na, K, Ca, Fe, Cu, Mg, Mn, Li, Al, Cr, Ni, and Zn is 5, 4, 3, 2, 1, 0.5, 0.1, 0.05, 0.01, 0.005, or 0.001 ppb or less. In some embodiments, the metal element concentration of each of Na and Ca is 0.75 ppb or less, Al, K, Fe, Mg, and Zn is 0.25 ppb or less, and Cu, Mn, Li, Cr, and Ni is 0.1 ppb or less. In some embodiments, the bio-based developer comprises 0.001-1 ppb of metal element concentration of each of Na, K, Ca, Fe, Cu, Mg, Mn, Li, Al, Cr, Ni, and Zn.

Organic compounds or impurities may also create contamination issues in the semiconductor manufacturing process. In addition to minimizing the amounts of impurities in the solvent, it is necessary to reduce or eliminate organic impurities as well. In particular, relatively low molecular weight organic compounds pose a significant challenge to semiconductor processes as they can be challenging to remove via filtration techniques and form particle contamination, especially, a fine pattern (for example, 30 nm node or less). In some embodiments, the bio-based NBA negative developer comprises 5 ppb or less of an alkane or alkene having a carbon number of 22 or less (“C₁₋₂₂ alkane/alkene”). In some embodiments, the bio-based NBA negative developer comprises 5, 4, 4, 2, 1, 0.5, 0.1, 0.05, or 0.01 ppb or less of C₁₋₂₂ alkane/alkene. In some embodiments, the concentration of C₁₋₂₂ alkane/alkene is from 0.001-1 ppb. The content of C₁₋₂₂ alkane/alkene may be measured according to a gas chromatography mass spectrometry (e.g., GCMS-QP2010 (a gas chromatography mass spectrometer) manufactured by Shimadzu Corporation) connected to a pyrolysis apparatus (e.g., PY2020D manufactured by Frontier Lab).

Additional organic solvents may be present in small amounts as a result of the synthetic techniques used. In some embodiments, it is necessary to reduce or remove these impurities or intermediates. Such compounds include, but are not limited to, bio-based n-butanol, n-hexadecane, isopropanol, and ethyl acetate. In some embodiments, the bio-based NBA negative developer comprises 3, 2, 1, 0.5, 0.1, 0.05, 0.01, or 0.001% or less bio-based n-butanol. In some embodiments, the bio-based NBA negative developer comprises 3, 2, 1, 0.5, 0.1, or 0.5% or less of one or more of bio-based n-butanol, n-hexadecane, isopropanol, and ethyl acetate. In some embodiments, the bio-based NBA negative developer comprises 3, 2, 1, 0.5, 0.1, 0.05, 0.01, or 0.001% or less of total other (non NBA) bio-based solvents.

In addition to metals and low molecular weight organics, general particle contamination comprising nano- to microscale particulates stemming from various other sources also results in device defects that negatively impact yield. Therefore, as noted above, it is critical that any trace particles be removed from the bio-based solvents. Specifically, according to the purification method, the number of particles having a particle size of 0.15 μm or more contained in the solvent can be, for example, 20 particles/mL or less, 10 particles/mL or less, or 5 particles/mL or less. Particle count is measured by liquid particle count techniques as well as on wafer measurements. For example, after depositing a specified amount of solvent on a substrate and spinning it off at a specified number of revolutions, the wet particle amount is further dried at a specified number of revolutions, and then the number of defects on the substrate is determined by, for example, a KLA Surfscan SP7 unpatterned wafer inspection system.

The bio-based negative developer may further comprise additional components, such as surfactants and stabilizers. The surfactant is not particularly limited but, for example, ionic or nonionic fluorine-based and/or silicon-based surfactant and the like may be used. Examples of the fluorine and/or silicon-based surfactant include surfactants described in Japanese Patent Application Laid-Open Nos. S62-36663, S61-226746, S61-226745, S62-170950, S63-34540, H7-230165, H8-62834, H9-54432 and H9-5988, and U.S. Pat. Nos. 5,405,720, 5,360,692, 5,529,881, 5,296,330, 5,436,098, 5,576,143, 5,294,511 and 5,824,451, and a nonionic surfactant is preferred. The nonionic surfactant is not particularly limited, but a fluorine-based surfactant or a silicon-based surfactant is more preferably used. When present, the amount of the surfactant in use ranges usually from 0.001 wt % to 5 wt %, from 0.005 wt % to 2 wt %, or from 0.01 wt % to 0.5 wt %, based on the total amount of the developer.

The bio-based negative developer may further comprise a nitrogen-containing enhancer compound that, when included in the developer, interacts with a polar group that is produced in the resist film due to an acid, and further increases the insolubility of the exposed area in the organic solvent. For example, the nitrogen-containing enhancer compound reacts with the polar group to form a salt or an ionic bond. In view of, for example, the storage stability of the developer, the nitrogen-containing enhancer compound may be added to the organic developer preferably immediately before the pattern forming method of the present invention is performed. The enhancer compound has the following structure:

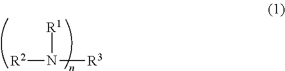

wherein R¹, R² and R³ individually represent a hydrogen atom, a hydroxyl group, a formyl group, an alkoxy group, an alkoxycarbonyl group, an optionally substituted C₁₋₃₀ alkyl group, an optionally substituted C₃₋₃₀ cycloalkyl or aryl group, or a group formed by two or more of these groups, and two of R¹, R² and R³ may bond to form a cyclic structure together with the nitrogen atom bonded thereto

In embodiments where an enhancer compound is present, the amount of the enhancer compound ranges from 0.001 wt % to 10 wt %, from 0.1 wt % to 10 wt %, or from 1 wt % to 5 wt %, based on the total amount of the developer.

### Bio-Based Rinsing Solution

The bio-based rinsing solution comprises a bio-based material that improves quality of the patterned photoresist. The bio-based rinsing solution can be either partially or totally derived from at least one bio-based material. The bio-based rinsing solution may comprise a hydrocarbon-based solvent, a ketone-based solvent, an ester-based solvent, an alcohol-based solvent or an amide-based solvent, or a combination or one or more of said solvents, or may, in some embodiments, comprise an alcohol-based solvent in combination with an ester-based solvent.

As in the case of the negative developer, the bio-based rinsing solution needs to be of high to ultra-high purity. It is critical that the semiconductor wafer surface is not contaminated with any metallic impurities present in the NBA. Therefore, minimizing the metal impurity content of materials used in these processes is demanded as a matter of course. Solvents must be purified to extremely low-level metal content. The metal element concentration may be measured according to inductively coupled plasma mass spectrometry (e.g., an inductively coupled plasma mass spectrometer, Agilent 7500cs (ICP-MS equipment) manufactured by Agilent Technologies, Inc.). The bio-based rinsing solution should comprise 5 ppb or less of metal element concentration of each of Na, K, Ca, Fe, Cu, Mg, Mn, Li, Al, Cr, Ni, and Zn. In some embodiments, the metal element concentration of each of Na, K, Ca, Fe, Cu, Mg, Mn, Li, Al, Cr, Ni, and Zn is 5, 4, 3, 2, 1, 0.5, 0.1, 0.05, 0.01, 0.005, or 0.001 ppb or less. In some embodiments, the metal element concentration of each of Na and Ca is 0.75 ppb or less, Al, K, Fe, Mg, and Zn is 0.25 ppb or less, and Cu, Mn, Li, Cr, and Ni is 0.1 ppb or less. In some embodiments, the bio-based rinsing solution comprises 0.001-1 ppb of metal element concentration of each of Na, K, Ca, Fe, Cu, Mg, Mn, Li, Al, Cr, Ni, and Zn.

Organic compounds or impurities may also create contamination issues in the semiconductor manufacturing process. In addition to minimizing the amounts of impurities in the solvent, it is necessary to reduce or eliminate organic impurities as well. In particular, relatively low molecular weight organic compounds pose a significant challenge to semiconductor processes as they can be challenging to remove via filtration techniques and form particle contamination, especially, a fine pattern (for example, 30 nm node or less). In some embodiments, the bio-based NBA negative developer comprises 5 ppb or less of an alkane or alkene having a carbon number of 22 or less (“C₁₋₂₂ alkane/alkene”). In some embodiments, the bio-based NBA negative developer comprises 5, 4, 4, 2, 1, 0.5, 0.1, 0.05, or 0.01 ppb or less of C₁₋₂₂ alkane/alkene. In some embodiments, the concentration of C₁₋₂₂ alkane/alkene is from 0.001-1 ppb. The content of C₁₋₂₂ alkane/alkene may be measured according to a gas chromatography mass spectrometry (e.g., GCMS-QP2010 (a gas chromatography mass spectrometer) manufactured by Shimadzu Corporation) connected to a pyrolysis apparatus (e.g., PY2020D manufactured by Frontier Lab).

Additional organic solvents may be present in small amounts as a result of the synthetic techniques used. In some embodiments, it is necessary to reduce or remove these impurities or intermediates. In some embodiments, the bio-based rinsing solution comprises 3, 2, 1, 0.5, 0.1, 0.05, 0.01, or 0.001% or less of total other bio-based solvents.

In addition to metals and low molecular weight organics, general particle contamination comprising nano- to microscale particulates stemming from various other sources also results in device defects that negatively impact yield. Therefore, as noted above, it is critical that any trace particles be removed from the bio-based solvents. Specifically, according to the purification method, the number of particles having a particle size of 0.15 μm or more contained in the solvent can be, for example, 20 particles/mL or less, 10 particles/mL or less, or even 5 particles/mL or less. Particle count is measured by liquid particle count techniques as well as on wafer measurements. For example, after depositing a specified amount of solvent on a substrate and spinning it off at a specified number of revolutions, the wet particle amount is further dried at a specified number of revolutions, and then the number of defects on the substrate is determined by, for example, a KLA Surfscan SP7 unpatterned wafer inspection system.

The bio-based rinsing solution may be characterized by its Hansen solubility parameters. In some embodiments, the bio-based solvent herein should have a dispersion parameter of about 14.5-17 MPa^{0.5}, and the sum of a polarity parameter and a hydrogen bonding parameter is about 14-20 MPa^{0.5}. In some embodiments, a selected solvent has a dispersion parameter value of about 15 to 16 MPa^{0.5}, or for example from 15.4 to 15.9 MPa^{0.5}; and a sum of the polarity parameter and the hydrogen bonding parameter is 15 to about 19 MPa^{0.5}, more preferably from 15.5 to 18.5 MPa^{0.5}.

In the present disclosure, the ketone-based rinsing solution indicates a solvent having a ketone group within the molecule, the ester-based solvent indicates a solvent having an ester group within the molecule, the alcohol-based solvent indicates a solvent having an alcoholic hydroxyl group within the molecule, the amide-based solvent indicates a solvent having an amide group within the molecule, and the ether-based solvent indicates a solvent having an ether bond within the molecule. Some of these solvents have a plurality of kinds of the functional groups described above within one molecule and in this case, the solvent comes under all solvent species corresponding to the functional groups contained in the solvent. For example, diethylene glycol monomethyl ether comes under both an alcohol-based solvent and an ether-based solvent in the classification above. The hydrocarbon-based solvent indicates a hydrocarbon solvent having no substituent.

Examples of the ketone-based rinsing solution include 2-heptanone, 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, 4-methyl-2-pentanone, acetylacetone, acetonylacetone, ionone, diacetonyl alcohol, acetylcarbinol, acetophenone, methyl naphthyl ketone, isophorone, propylene carbonate, γ-butyrolactone, γ-valerolactone, and dihydrolevoglucosenone. Of ketone-based solvents, 2-heptanone is most preferred.

Examples of the ester-based rinsing solution include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl benzoate, ethyl-3-methoxypropionate, ethyl-3-ethoxypropionate, propyl-3-methoxypropionate. As for the solvent represented by formula (1), an alkyl acetate is still more preferred, and butyl acetate is most preferred.

As for the ester-based rinsing solution, a solvent represented by formula (1) described later or a solvent represented by formula (2) described later is preferred, a solvent represented by formula (1) is more preferred, an alkyl acetate is still more preferred, and butyl acetate is most preferred.

Examples of the alcohol-based rinsing solution include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl methyl isobutyl carbinol, alcohol, n-heptyl alcohol, n-octyl alcohol, n-decanol and 3-methoxy-1-butanol; a glycol-based solvent such as ethylene glycol, diethylene glycol and triethylene glycol; and a hydroxyl group-containing glycol ether-based solvent such as ethylene glycol monomethyl ether, propylene glycol monomethyl ether, ethylene glycol, diethylene glycol monomethyl ether, triethylene glycol monoethyl ether, methoxymethyl butanol, ethylene glycol monoethyl ether, ethylene glycol monopropyl ether, ethylene glycol monobutyl ether, propylene glycol monoethyl ether, propylene glycol monopropyl ether, propylene glycol monobutyl ether and propylene glycol monophenyl ether. Among these, a glycol ether-based solvent is preferred.

Examples of the ether-based rinsing solution include, in addition to the hydroxyl group-containing glycol ether-based solvents above, a hydroxyl group-free glycol ether-based solvent such as propylene glycol dimethyl ether, propylene glycol diethyl ether, diethylene glycol dimethyl ether and diethylene glycol diethyl ether; dioxane; tetrahydrofuran; anisole; perfluoro-2-butyltetrahydrofuran; and 1,4-dioxane. A glycol ether-based solvent is preferably used.

Examples of the hydrocarbon-based rinsing solution include an aromatic hydrocarbon-based solvent such as toluene and xylene, an aliphatic hydrocarbon-based solvent such as pentane, hexane, octane, decane, 2,2,4-trimethylpentane, 2,2,3-trimethylhexane, perfluorohexane and perfluoroheptane, and an aromatic hydrocarbon-based solvent such as toluene, xylene, ethylbenzene, propylbenzene, 1-methylpropylbenzene, 2-methylpropylbenzene, dimethylbenzene, diethylbenzene, ethylmethylbenzene, trimethylbenzene, ethyldimethylbenzene and dipropylbenzene. Among these, an aromatic hydrocarbon-based solvent is preferred.

In some embodiments, the bio-based rinsing solution most comprises a monohydric alcohol having a carbon number of 6 to 8. The monohydric alcohol having a carbon number of 6 to 8 includes a linear, branched or cyclic monohydric alcohol, and specific examples of the monohydric alcohol which can be used include a 1-hexanol, 1-heptanol, 1-octanol, 2-hexanol, 2-heptanol, 2-octanol, 3-hexanol, 3-heptanol, 3-octanol, 4-octanol, methyl isobutyl carbinol, and benzyl alcohol, with 1-hexanol, methyl isobutyl carbinol, 2-hexanol, 1-heptanol, and 2-heptanol being preferred, with methyl isobutyl carbinol being most preferred.

A plurality of these solvents may be mixed, or the solvent may be mixed with a solvent other than those described above or water and used.

### Bio-Based Solvents for Solubilizing Photoresists

The bio-based solvents described herein may, in some embodiments, be used as or incorporated into formulations for photoresist compositions. Photoresist compositions generally include a solvent for dissolving the components of the composition and facilitating its coating on a substrate. Due to toxicological, environmental, and especially flammability issues, there are a limited number of organic solvents that are compatible with practical industrial-scale semiconductor manufacturing.

Photoresist compositions of the present disclosure comprise (A) a polymer matrix of which solubility in an alkali developer increases and solubility in an organic solvent decreases under the action of an acid; (B) a compound capable of generating an acid upon irradiation with actinic rays or radiation (sometimes referred to as a “photoacid generator”; (C) a bio-based solvent which can be used for dissolving respective components of the photoresist composition that comprises at least 0.1 dpm/gC (disintegrations per minute per gram carbon) of carbon-14 (C-14), and optionally, one or more of the following: (D) basic compound, (E) surfactant, (F) photo-decomposable quencher, and (G) other additives.

In another embodiment, the photoresist composition includes a class of radiation-based resists based on metal oxide chemistry (metal oxo/hydroxo compositions), which uses radiation sensitive ligands to control stability and processability of the resists. In general, these resist compositions function as negative tone photoresists when developed with organic solvents. Related resist compounds are discussed in U.S. Pat. No. 8,703,386B2, herein incorporated by reference. Organometallic photoresists such as organotin oxide hydroxides have been shown to possess excellent properties as photoresists for use in lithographic photopatterning. Suitable organometallic photoresists include organotin materials as described in U.S. Pat. No. 9,310,684B2, published U.S. patent application 2016/0116839A1, and U.S. Pat. No. 10,228,618B2, all of which are incorporated herein by reference. Other organometallic patterning compositions based on various metals are described in published U.S. patent application 2002/0076495 and U.S. Pat. No. 9,372,402B2, both of which are incorporated herein by reference. Resists with metal oxide particles having organic coatings are described in published U.S. patent application 2015/0234272A1, herein incorporated by reference. Applicant has developed organotin patterning materials that have been progressed to a high degree, and some of these are described in the exemplified compositions.

Typical solvents used in photoresist compositions include n-butyl acetate (NBA), 2-heptanone, propylene glycol monomethyl ether acetate (PGMEA), propylene glycol monomethyl ether (PGME), hydroxyisobutyrate methyl ester (HBM), and cyclohexanone (CHO). The total solvent content in photoresist compositions is typically 70 to 99 wt % based on total weight of the photoresist composition. The present disclosure contemplates use of NBA alone or as part of a mixture of one or more solvents. The percentage of NBA includes those listed herein for mixtures, for example from 5-99 wt %.

As in the case of the negative developer and rinse, the bio-based photoresist solvent needs to be of high to ultra-high purity. Solvents must be purified to extremely low-level metal content. The metal element concentration may be measured according to inductively coupled plasma mass spectrometry (e.g., an inductively coupled plasma mass spectrometer, Agilent 7500cs (ICP-MS equipment) manufactured by Agilent Technologies, Inc.). The bio-based rinsing solution should comprise 5 parts per million (ppb) or less of metal element concentration of each of Na, K, Ca, Fe, Cu, Mg, Mn, Li, Al, Cr, Ni, and Zn. In some embodiments, the metal element concentration of each of Na, K, Ca, Fe, Cu, Mg, Mn, Li, Al, Cr, Ni, and Zn is 5, 4, 3, 2, 1, 0.5, 0.1, 0.05, 0.01, 0.005, or 0.001 ppb or less. In some embodiments, the metal element concentration of each of Na and Ca is 0.75 ppb or less, Al, K, Fe, Mg, and Zn is 0.25 ppb or less, and Cu, Mn, Li, Cr, and Ni is 0.1 ppb or less. In some embodiments, the bio-based rinsing solution comprises 0.001-1 ppb of metal element concentration of each of Na, K, Ca, Fe, Cu, Mg, Mn, Li, Al, Cr, Ni, and Zn.

As noted previously, organic compounds or impurities may also create contamination issues in the semiconductor manufacturing process. In addition to minimizing the amounts of impurities in the solvent, it is necessary to reduce or eliminate organic impurities as well. In particular, relatively low molecular weight organic compounds pose a significant challenge to semiconductor processes as they can be challenging to remove via filtration techniques and form particle contamination, especially, a fine pattern (for example, 30 nm node or less). In some embodiments, the bio-based rinsing solution comprises 5 ppb or less of an alkane or alkene having a carbon number of 22 or less (“C₁₋₂₂ alkane/alkene”). In some embodiments, the bio-based rinsing solution comprises 5, 4, 4, 2, 1, 0.5, 0.1, 0.05, or 0.01 ppb or less of C₁₋₂₂ alkane/alkene. In some embodiments, the concentration of C₁₋₂₂ alkane/alkene is from 0.001-1 ppb. The content of C₁₋₂₂ alkane/alkene may be measured according to a gas chromatography mass spectrometry (e.g., GCMS-QP2010 (a gas chromatography mass spectrometer) manufactured by Shimadzu Corporation) connected to a pyrolysis apparatus (e.g., PY2020D manufactured by Frontier Lab).

Additional organic solvents may be present in small amounts as a result of the synthetic techniques used. In some embodiments, it is necessary to reduce or remove these impurities or intermediates. In some embodiments, the bio-based rinsing solution comprises 3, 2, 1, 0.5, 0.1, 0.05, 0.01, or 0.001% or less of total other bio-based solvents.

In addition to metals and low molecular weight organics, general particle contamination comprising nano- to microscale particulates stemming from various other sources also results in device defects that negatively impact yield. Therefore, as noted above, it is critical that any trace particles be removed from the bio-based solvents. Specifically, according to the purification method, the number of particles having a particle size of 0.15 μm or more contained in the solvent can be, for example, 20 particles/mL or less, 10 particles/mL or less, or even 5 particles/mL or less. Particle count is measured by liquid particle count techniques as well as on wafer measurements. For example, after depositing a specified amount of solvent on a substrate and spinning it off at a specified number of revolutions, the wet particle amount is further dried at a specified number of revolutions, and then the number of defects on the substrate is determined by, for example, a KLA Surfscan SP7 unpatterned wafer inspection system.

The bio-based solvent can be characterized by its Hansen solubility parameters. The bio-based solvent herein should have a dispersion parameter of about 14.5-17 MPa^{0.5}, and the sum of a polarity parameter and a hydrogen bonding parameter is about 14-20 MPa^{0.5}. More in particular, a selected solvent has a dispersion parameter value of about 15 to 16 MPa^{0.5}, or for example from 15.4 to 15.9 MPa^{0.5}; and a sum of the polarity parameter and the hydrogen bonding parameter is 15 to about 19 MPa^{0.5}, more preferably from 15.5 to 18.5 MPa^{0.5}.

The resin binder of the present invention is preferably a poorly alkali soluble or alkali insoluble binder comprising one or more blocked (masked) alkali solubilizing groups (acid sensitive groups). The functionality blocking some or all of the alkali solubilizing groups is acid sensitive. The presence of an acid catalyzes the deblocking of the alkali solubilizing group and renders the polymer alkali soluble. Suitable alkali solubilizing groups include, but are not limited to, carboxylic acids, sulfonic acid, phenols, acidic alcohols, hydroxyimides, hydroxymethylimides, and silanols. Suitable acidic hydroxyl, carboxyl and sulfamido groups are further described in U.S. Patent Appl. 2006/0110677.

The photoactive compound capable of generating a strong acid upon exposure to a source of high energy radiation is commonly referred to as a photoacid generator, or PAG. Any suitable photoacid generator may be used in the photosensitive compositions of the present invention. One skilled in the art would be able to choose the appropriate PAG based upon such factors as acidity, catalytic activity, volatility, diffusivity, and solubility. Suitable classes of PAGs generating sulfonic acids include, but are not limited to, sulfonium or iodonium salts, oximidosulfonates, bissulfonyldiazomethanes, and nitrobenzylsulfonate esters. Suitable photoacid generator compounds are disclosed, for example, in U.S. Pat. Nos. 5,558,978, 5,468,589, 6,844,132, 6,855,476, and 6,911,297 which are incorporated herein by reference. Preferred PAGs are tris(perfluoroalkylsulfonyl)methides, tris(perfluoroalkylsulfonyl)imides, and those generating perfluoroalkylsulfonic acids.

Additional examples of suitable photoacid generators for use in this invention include, but are not limited to, triphenylsulfonium perfluorooctanesulfonate, triphenylsulfonium perfluorobutanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl)sulfonium perfluorooctanesulfonate, tris(-t-butylphenyl)sulfonium perfluorobutanesulfonate, tris(-t-butylphenyl)sulfonium 2,4,6-triisopropylbenzenesulfonate, tris(-t-butylphenyl)sulfonium benzenesulfonate, and phenylthiophenyldiphenylsulfonium perfluorooctanesulfonate.

Examples of suitable iodonium salts for use in this invention include, but are not limited to, diphenyl iodonium perfluorobutanesulfonate, bis-(t-butylphenyl)iodonium perfluorobutanesulfonate, bis-(t-butylphenyl)iodonium, perfluorooctanesulfonate, diphenyl iodonium perfluorooctanesulfonate, bis-(t-butylphenyl)iodonium benzenesulfonate, bis-(t-butylphenyl)iodonium 2,4,6-triisopropylbenzenesulfonate, and diphenyliodonium 4-methoxybenzensulfonate.

Examples of tris(perfluoroalkylsulfonyl)methide and tris(perfluoroalkylsulfonyl)imide PAGs 5 that are suitable for use in the present invention can be found in U.S. Pat. Nos. 5,554,664 and 6,306,555, each of which is incorporated herein in its entirety. Additional examples of PAGs of this type can be found in Proceedings of SPIE, Vol. 4690, pp. 817-828 (2002). Suitable methide and imide PAGs include, but are not limited to, triphenylsulfonium tris(trifluoromethylsulfonyl)methide, methylphenyldiphenylsulfonium tris(perfluoroethylsulfonyl)methide, triphenylsulfonium tris(perfluorobutylsulfonyl)methide, triphenylsulfonium bis(trifluoromethylsulfonyl)imide, triphenylsulfonium bis(perfluoroethylsulfonyl)imide, and triphenylsulfonium bis(perfluorobutylsulfonyl)imide.

Further examples of suitable photoacid generators for use in this invention are bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, 2,4-dinitrobenzyl p-trifluoromethylbenzenesulfonate.

More preferred PAGs are triarylsulfonium perfluoroalkylsulfonates and triarylsulfonium tris(perfluoroalkylsulfonyl)methides. Most preferred PAGs are triphenylsulfonium perfluorooctanesulfonate (TPS-PFOS), triphenylsulfonium perfluorobutanesulfonate (TPS-Nonaflate), methyiphenyldiphenylsulfonium perfluorooctanesulfonate (TDPS-PFOS), tris(-t-butylphenyl)sulfonium perfluorobutanesulfonate (TTBPS-Nonaflate), triphenylsulfonium tris(trifluoromethylsulfonyl)methide (TPS-C1) and methylphenyldiphenylsulfonium tris(perfluoroethylsulfonyl)methide.

The total photoacid generator content of the photosensitive composition is from about 0.05 wt % to about 20 wt % of the total solids content. The preferred range is from about 1 wt % to about 15 wt %. The photoacid generator may be used alone or in combination with one or more photoacid generators. The percentage of each PAG in the photoacid generator mixture is between about 10 wt % to about 90 wt % of the total photoacid generator mixture. Preferred photoacid generator mixtures contain about 2 or 3 photoacid generators. Such mixtures may be of the same class or different classes. Examples of preferred mixtures include sulfonium salts with bissulfonyldiazomethane compounds, sulfonium salts and imidosulfonates, and two sulfonium salts.

Base additives may also be added to the photosensitive composition as quenchers to act as diffusion control agents. One purpose of the base additive is to scavenge protons present in the photosensitive composition prior to being irradiated by the actinic radiation. The base prevents attack and cleavage of the acid labile groups by the undesirable acids, thereby increasing the performance and stability of the photosensitive composition. In addition, the base can act as a diffusion control agent to prevent the photogenerated acid from migrating too far after exposure and lowering resolution. The percentage of base in the photosensitive composition should be significantly lower than the photoacid generator or otherwise the photosensitivity becomes too low. The preferred range of the base compounds, when present, is from about 3 wt % to about 50 wt % of the photoacid generator compound. Suitable examples of base additives include, but are not limited to, cyclopropylamine, cyclobutylamine, cyclopentylamine, dicyclopentylamine, dicyclopentylmethylamine, dicyclopentylethylamine, cyclohexylamine, dimethylcyclohexylamine, dicyclohexylamine, dicyclohexylmethylamine, dicyclohexylethylamine, dicyclohexylbutylamine, cyclohexyl-t-butylamine, cycloheptylamine, cyclooctylamine, 1-adamantanamine, 1-dimethylaminoadamantane, 1-diethylaminoadamantane, 2-adamantanamine, 2-dimethylaminoadamantane, 2-aminonorbornene, and 3-noradamantanamine, 2-methylimidazole, tetramethyl ammonium hydroxide, tetrabutylammonium hydroxide, triisopropylamine, triocylamine, tridodecylamine, 4-dimethylaminopryidine, 4,4′-diaminodiphenyl ether, 2,4,5-triphenylimidazole, 1,4-diazabicyclo[4.3.0]non-5-ene and 1,5-diazabicyclo[4.3.0]non-5-ene, and 1,8-diazabicyclo[5.4.0]undec-7-ene, guanidine, 1,1-dimethylguanidine, 1,1,3,3-tetramethylguanidine, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, N-(2-aminoethyl)morpholine, trimethylimidazole, triphenylimidazole, and methyldiphenylimidazole. More preferred base additives are tridodecylamine, 2,4,5-triphenyl imidazole, 1,5-diazobicyclo[4.3.0]non-5-ene and 1,8-diazobicyclo[5.4.0]undec-7-ene.

### Production of Bio-Based Solvents

Bio-based solvents can be derived from bio-based materials, including sugars, starches, corns, natural fibers, sugarcanes, beets, citrus fruits, woody plants, cellulosics, lignocelluosics, hemicelluloses, potatoes, plant oils, other polysaccharides such as pectin, chitin, levan, and pullulan, and combinations thereof. According to a particular embodiment, at least one bio-based material is selected from corn, sugarcane, beet, potato, starch, citrus fruit, woody plant, cellulosic lignin, plant oil, natural fiber, oily wood feedstock, and combinations thereof.

Use of bio-based materials to create homogenous chemicals involves dramatically different processes from fossil fuel feedstocks. Crude oil feedstock has low functionality which makes it directly suitable for use as a solvent or fuel after prior processing (for example cracking and isomerisation). Functional groups, such as C═O and OH, are added to crude oil derived feedstock to produce bulk and specialty chemicals. Here, special care is taken to ensure selective addition of the functional group without over functionalization of the substrates. Contrastingly, biomass derived feedstocks, such as cellulose and hemicellulose, contain far too much functionality to use directly as fuels or bulk chemicals, and therefore require selective strategies for isolation and defunctionalization.

The three conversion technologies for carbohydrates and cellulose include biological conversion (enzymatic fermentation), catalytic conversion (dehydration, rehydration, hydrogenation, hydrolysis, aldo condensation, hydrogenolysis, oxidation, etc.), and thermochemical and thermocatalytic conversion. Although production of first-generation biofuels (bio-ethanol and biobutanol) is well established, this process relies on starch and sugar feeds which compete with the food chain. Hydrolysis of cellulosic feedstock to fermentable sugars has been achieved as alternative routes to bio-alcohols as fuels in order to avoid food sources as feedstock. However, slow reaction rate, high cost and sensitivity of enzymes and energy intensive subsequent distillation and drying steps remain challenges to achieving cost-effectiveness in these processes. Thermocatalytic conversions offer an alternative to enzymatic fermentation for transforming biomass (such as wood, sugarcane bagasse or corn stover) to aromatic compounds. For example, processes have been developed that uses zeolite-based catalysts to produce gases which are then converted to benzene, xylene and toluene (bio-BTX). Thermochemical processes such as gasification, pyrolysis, torrefaction and liquefaction require intense heating at elevated temperatures, therefore raising energy efficiency concerns. In addition, the selectivity in bio-oils produced from pyrolysis is extremely poor, therefore inevitably requiring expensive additional upgrading and separation steps. Finally, use of catalytic conversion of cellulosic biomass and cellulose derived intermediates to fuels, fuel additives and chemicals may be used. Multiple types of catalysts have shown potential in this space, for example noble metal catalyst systems for use in a variety of the key reaction steps, such as hydrolysis, dehydration, hydrodeoxygenation (HDO), hydrogenation and oxidation leading to value added products from cellulosic biomass. Examples of catalytically derived compounds include 5-hydroxymethylfurfural, furfural, and acetic acid. However, high catalyst costs and catalyst poisoning continue to pose issues for these processes.

Recent advances in gene editing have the potential to open the field of bio-based solvent production. Clustered regularly interspaced short palindromic repeats (CRISPR) and the CRISPR-associated (Cas) system is an RNA guided immune system in bacteria and archaea that has been engineered to be a high efficient genome editing tool that has been implemented in a broad range of organisms, such as bacteria, yeast, plants, mammal cells, and human cells. Besides single gene knock-in or knock-out, successes have also been reported for multiplex genome editing and transcriptional regulation, including repression and activation.

Clostridia are a type of bacteria that have long been studied for biobutanol production through its acetone-butanol-ethanol (ABE) fermentation pathway. Although tremendous efforts have been invested on the metabolic engineering of solventogenic clostridial strains for enhanced biobutanol production, only very limited success has been achieved. This is because, on one hand, there are several intrinsic byproducts in ABE fermentation including fatty acids, acetone and ethanol that are hard to eliminate; on the other, the ABE fermentation for butanol production goes through a biphasic process and is subjected to complicated metabolic regulation. Recent efforts have focused on modifying the ABE fermentation pathway of clostridia in order to reduce unwanted byproducts while increasing overall yield of butanol. One method used to achieve these modifications involves the use of CRISPR-Cas9 systems.

In one process, as described in U.S. Pat. No. 11,142,751 B2, herein incorporated by reference, the endogenous CRISPR-Cas system of C. tyrobutyricum, was used to successfully engineer C. tyrobutyricum for enhanced butanol production. By introducing an adhE2 gene and inactivating the native cat1 gene, the obtained mutant produced a record high of 26.2 g/L butanol in a batch fermentation.

Additionally, production of bio-based butyl acetate has been demonstrated using microbial fermentation of glucose by butanol-producing Clostridium acetobutylicum NJ4 with the supplementation of exogenous acetic acid; by acetate-producing Actinobacillus succinogenes130z (ΔpflA) with the addition of exogenous butanol; and a microbial co-culture system of C. acetobutylicum NJ4 and A. succinogenes130z (ΔpflA) with the elimination of exogenous precursors (14 Biotechnol. Biofuels 203 (2021)).

Alternatively, bio-based butyl acetate has also been produced by leveraging pathways in solventogenic clostridia for co-producing acyl-CoAs, acids and alcohols as precursors, combined with systematic metabolic engineering, resulting in strains that can produce 20.3 g/L butyl acetate (12 Nat. Commun. 4368 (2021)). Bio-based acetates such as n-butyl acetate can also be prepared from the corresponding bio-based alcohols, n-butanol, via direct Fischer esterification and transesterification reactions with bio-based acetic acid or acetate esters.

These fermentation processes produce mixtures of the desired butyl acetate along with significant levels of intermediates and impurities. For example, Yi Wang in a DOE Bioenergy Technologies Office (BETO), 2021 Project Peer Review, titled “Bioproduction and Evaluation of Renewable Butyl Acetate as a Desirable Bioblendstock for Diesel Fuel”, and presented on Mar. 16, 2021, disclosed the following composition in butyl acetate production:

| Chemical | NBA | n-butanol | n-hexadecane | isopropanol | Ethyl acetate | unknown |
|---|---|---|---|---|---|---|
| Mass fraction (%) | 94.3 | 3.8 | 0.4 | 0.134 | 0.118 | 1.248 |

A two-step biobased process, described in U.S. Pat. Publ. No. 2014/0329275, can convert glucose into methyl isobutyl ketone (MIBK), diisobutyl ketone (DIBK) or methyl isoamyl ketone (MIAK). The process utilizes a modified microbe that converts glucose into isovaleric acid and isocaproate. These intermediate chemicals can then be converted to the corresponding ketones. These ketones can then be reduced to the corresponding alcohols, methyl isobutyl carbinol (MIBC), diisobutyl carbinol (DIBC) or methyl isoamyl carbinol (MIAC).

U.S. Pat. No. 8,298,798 describes metabolically-modified microorganisms useful for producing biofuels including higher alcohols including C5-C8 alcohol from bio-based feedstocks like glucose. The methods are capable of producing C5 alcohols such as 2-methyl-1-butanol, 3-methyl-1-butanol, and 1-pentanol; C6 alcohols such as 3-methyl-1-pentanol, and 1-hexanol; C7 alcohols such as 2-isopropyl-1-butanol, and the C8 alcohol 5-methyl-1-heptanol.

Bio-based alcohols such as hexanol can be produced by fermentation of syngas using Clostridium carboxidivorans P7 according to the methods described in 10 Front. Bioeng. Biotechnol., art. 850370 (2022). Bio-based heptanol can be prepared by catalytic hydrocracking—hydrogenation of Castor Oil fatty acid methyl esters as described in 1 ChemistrySelect 6396 (2016)).

Process steps not specifically described herein and additional synthetic methods may further be found in such references as, Synthesis and industrial production of bio-solvents is reviewed in Oklu, et al., Bio-Solvents: Synthesis, Industrial Production and Applications, in Solvents, Ionic Liquids and Solvent Effects, IntechOpen, London (2019).

### Purification of Bio-Based Solvents

As noted previously, solvents used in semiconductor manufacturing processes typically must be of high to ultra-high purity. It is critical that the semiconductor wafer surface is not contaminated with any metallic impurities present in the solvents as metals inhibit the functions of semiconductor elements. In fact, micro-contamination accounts for over 50% of yield loss in IC manufacturing. Therefore, minimizing the metal impurity content of materials used in these processes is demanded as a matter of course. Solvents must be purified to extremely low-level metal content, for example, several part per billion (ppb) to several part per trillion (ppt), is required for each metal, e.g., sodium, iron, etc.

Organic compounds or impurities may also create contamination issues in the semiconductor manufacturing process. In addition to minimizing the amounts of impurities in the solvent, it is necessary to reduce or eliminate organic impurities as well. In particular, relatively low molecular weight organic compounds pose a significant challenge to semiconductor processes as they can be challenging to remove via filtration techniques and form particle contamination, especially, a fine pattern (for example, 30 nm node or less). Possible ways that these organic impurities are introduced is through impure or unpurified solvents, or through the containers or tubing used in transporting or semiconductor forming processes. Therefore, considerable thought is required in how the solvent is purified as well as how the solvent is stored and the materials it is contact with in order to avoid an increase of impurities during storage or transport, a degeneration of components, a quantitative change in the composition, an increase of impure metal elements, or a decrease in quality caused by a deterioration of a photosensitive component due to light.

In addition to metals and low molecular weight organics, general particle contamination comprising nano- to microscale particulates stemming from various other sources also results in device defects that negatively impact yield. Therefore, as noted above, it is critical that any trace particles be removed from the bio-based solvents. While ideally the number of particles on a semiconductor surface would be zero, the number of sources make this nigh impossible. Processes for monitoring and detecting particle contamination are described in ISO 14644-1:2015 and ISO 21501-4, herein incorporated by reference.

While not limited to the descriptions herein, purification of the bio-based solvents generally uses one or more of distillation, physical or chemisorptive filtration, or an ion exchange membrane. Ultimately, the process or processes are used in such a manner as to obtain the necessary purity and levels of metals and low molecular weight organics as disclosed herein.

Distillation processes may be employed to purify bio-based solvents. Depending on the composition of the primary product from the employed process, a multi-phase distillation may be employed including a first distillation device which removes low boiling point impurities, a second distillation device which removes high boiling point impurities, and a third distillation device which removes trace water. The distillation devices are selected from multiple stage type, packing type distillation towers, or spiral spinning band type distillation towers. Spinning band type distillation towers are particularly useful to separate compounds and remove trace water to produce an electronic-grade purity solvent. Inside the spinning band type distillation tower there is equipped a spiral stirring column made of metal or Teflon which rotates at high speed to maximize the contact area of the vapor components evaporated in the tower and the liquid component condensed in the tower, so that high separation and purification efficiency can be attained through fast and effective gas-liquid equilibrium. By varying the rotation speed of the spiral stirring column in the spinning band type distillation tower, the separation efficiency can be regulated appropriately. The resultant high separation and purification efficiency makes it possible to remove the trace water and easily separate and purify the individual components having similar boiling points into an electronic grade purity.

When necessary, a metal removing step is employed which typically comprises contacting the bio-based solvent with an acidic cation exchange resin. Various metals, such as alkali metals, alkaline earth metals, and transition metals, e.g., sodium, potassium, calcium, iron, nickel, etc., can be removed by the metal removing step. Commercially available strongly acidic cation exchange resins can be used in the present invention. Among them, cation exchange resins of sulfonated styrene-divinylbenzene cross-linked polymer are preferred. There are two types of strongly acidic cation exchange resins, one is the porous-type made of porous resins and the other one is the gel type which is made of nonporous resins. Suitable acidic exchange resins are available from Rohm and Haas Company, e.g. AMBERLYST 15 acidic ion exchange resin. These AMBERLYST resins typically contain as much as 80,000 to 200,000 ppb of sodium and iron. Before being utilized in the process of the invention, the ion exchange resin should be treated with water and then a mineral acid solution to reduce the metal ion level. It is important that the ion exchange resin be rinsed with a solvent that is the same as, or at least compatible with, the solvent being purified. The procedure in this step may be similar to those procedures disclosed in U.S. Pat. Nos. 5,284,930 and 5,288,850. Generally, the cation-exchange procedure is conducted at any temperature, pressure, and flow rate which accomplishes the desired end result. Liquid Purifiers such as PURASOL and PROTEGO purifiers may be employed to remove metal impurities.

Microfilters may be provided before and after the ion exchange resin treatment in order to remove by filtration insoluble impurities contained in the solvent or fine particles which might be flown out from the ion exchange resins. A filter device having a filter medium having a pore size of 0.05 μm or less is typically used, and the solvent is circulated in the filter device, whereby the filter medium is passed twice or more. Liquid filters based on a variety of membrane and media may be used, for example MICROGARD series filters from Entegris. In some embodiments, the microfilters comprise a polytetrfluoroethylene filter material. Such methods enable efficient removal of insoluble foreign matters, particles, and metal impurities having high polarity in the solvent. Specifically, according to the purification method, the number of particles having a particle size of 0.15 μm or more contained in the solvent can be, for example, 20 particles/mL or less, 10 particles/mL or less, or even 5 particles/mL or less. Particle count is measured by liquid particle count techniques as well as on wafer measurements. For example, after depositing a specified amount of solvent on a substrate and spinning it off at a specified number of revolutions, the wet particle amount is further dried at a specified number of revolutions, and then the number of defects on the substrate is determined by, for example, a KLA Surfscan SP7 unpatterned wafer inspection system.

In addition to the above methods for purifying the solvent, further steps may include storing or handling the solvent in materials comprising a perfluoro resin, wherein the perfluoro resin comprises a polytetrafluoroethylene resin (PTFE), a tetrafluoroethylene-perfluoroalkylvinyl ether copolymer (PFA), a tetrafluoroethylene-hexafluoropropylene copolymer resin (FEP), an ethylene tetrafluoroethylene copolymer resin (ETFE), an ethylene chlorotrifluoroethylene copolymer resin (ECTFE), a polyvinylidene resin (PVDF), a polychlorotrifluoroethylene copolymer resin (PCTFE), or a polyvinyl fluoride resin (PVF) may be exemplified. Such materials may reduce the amount of low molecular weight organics, metal impurities and other particles in the solvent.

Further, according to the purification method, the amount of metal element concentration of each of Na, K, Ca, Fe, Cu, Mg, Mn, Li, Al, Cr, Ni, and Zn is preferably 5 ppb or less, and more preferably 3 ppb or less. It is most preferable that none of Na, K, Ca, Fe, Cu, Mg, Mn, Li, Al, Cr, Ni, and Zn are present. However, if any one of these metal elements is present, a minimum of the concentration of the existing metal element is generally 0.001 ppb or more. The metal element concentration of Na, K, Ca, Fe, Cu, Mg, Mn, Li, Al, Cr, Ni, and Zn may be measured according to an inductively coupled plasma mass spectrometry (e.g., an inductively coupled plasma mass spectrometer, Agilent 7500cs (ICP-MS equipment) manufactured by Agilent Technologies, Inc.).

### Pattern Formations Methods

The lithographic pattern forming system utilizes a phenomenon that the solubility of the resist film in a developer is varied through a chemical reaction triggered, by light irradiation, a resist causing the light-irradiated part to dissolve in a developer is called a positive system, and a resist causing the non-light-irradiated part to dissolve in a developer is called a negative system. The positive resist utilizes a chemical reaction such as polarity conversion for enhancing the solubility in a developer, and the negative resist utilizes bond formation between molecules, such as crosslinking reaction or polymerization reaction.

Since the advent of a resist for KrF excimer lasers (248 nm), an image forming method called chemical amplification has been used to compensate for sensitivity reduction caused by light absorption. Positive chemical amplification is an image forming method where an acid generator in the exposed area decomposes and the acid generated is used as a reaction catalyst in the baking after exposure (FEB: post exposure bake). The resulting catalyst then converts the alkali-insoluble group into an alkali-soluble group, and the exposed area is removed by alkali development, also known as positive tone development (PTD). In other words, the positive resist composition is a resin composition capable of forming a film of which solubility in an alkali developer increases and solubility in an organic solvent-containing developer decreases as a result of a chemical reaction triggered by exposure to irradiation.

Alternatively, a chemically amplified resist originally designed to be developed in the positive tone with aqueous base developer can instead be developed with negative-tone development (NTD) using an organic developer that removes the unexposed portion of the resist film, while the exposed regions remain unaffected. The resist contrast of the NTD process is determined by the solubility differences between the relatively nonpolar unexposed resist and the more polar resist material that is generated in the exposed regions of the film. In the present disclosure, a bio-based organic developer containing an organic solvent can be used as the negative developer.

As for material-related parameters, control of various physical values related to solubility of the positive resist composition in the developer and the organic solvent, such as solubility parameter, are effective for tuning performance. Specific examples thereof for the positive resist composition include the average molecular weight of polymer species, the molecular weight dispersity, the monomer compositional ratio, the polarity of monomers, the monomer sequence, the polymer blend and the addition of low molecular additive(s), and the addition of surfactant(s).

In the pattern forming method of the present disclosure, the step of forming a film on a substrate by using a resin composition of which solubility in a positive developer increases and solubility in a negative developer decreases upon irradiation with actinic rays or radiation, the step of exposing the film, the step of heating (baking, also called PEB (post exposure bake)) the film, and the step of effecting development of the film may be performed by generally known methods.

Also, specific examples of the process-related parameter include the film formation temperature and time, the temperature and time of post-heating after exposure, the temperature at development, the development time, the nozzle system (puddle method, dynamic spray, etc) of developing apparatus, and the rinsing method after development.

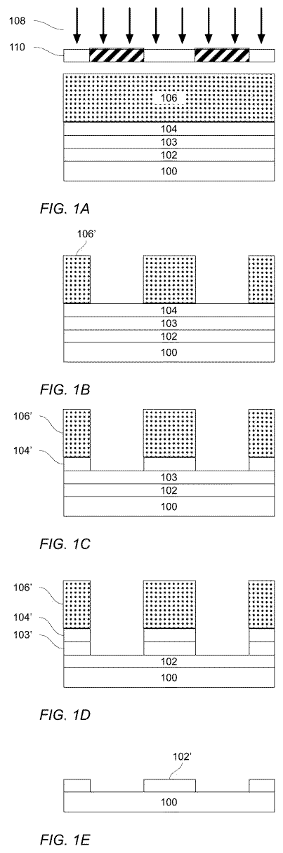

Non-limiting examples of processes in accordance with the disclosure will now be described with reference to FIG. 1A-E, which illustrates an exemplary process flow for a pattern formation method in accordance with the disclosure. While the illustrated process flow describes a patterning process in which a single resist mask is used to transfer the photoresist pattern to the underlying substrate, the method can be used in other lithographic processes, for example, in double patterning processes such as litho-litho-etch (LLE), litho-etch-litho-etch (LELE) or self-aligned double patterning (SADP), as an ion implantation mask, or any other lithographic process where such photoresist pattern treatment would be beneficial.

FIG. 1A depicts in cross-section a substrate 100 that may include various layers and features. The substrate can comprise a material such as a semiconductor (e.g., silicon) or compound semiconductor (e.g., III-V or II-VI), glass, quartz, ceramic, copper and the like. Typically, the substrate is a semiconductor wafer, such as single crystal silicon or compound semiconductor wafer, and may have one or more layers and patterned features formed on a surface. One or more layers to be patterned 102 may be provided over the substrate 100. Optionally, the underlying base substrate material itself may be patterned, for example, when it is desired to form trenches in the substrate material. In the case of patterning the base substrate material itself, the pattern is considered to be formed in a layer of the substrate.

The layers may include, for example, one or more conductive layers such as layers of aluminum, copper, molybdenum, tantalum, titanium, tungsten, alloys, nitrides or silicides of such metals, doped amorphous silicon or doped polysilicon, one or more dielectric layers such as layers of silicon oxide, silicon nitride, silicon oxynitride, or metal oxides, semiconductor layers, such as single-crystal silicon, and combinations thereof. The layers to be etched can be formed by various techniques, for example, chemical vapor deposition (CVD) such as plasma-enhanced CVD (PECVD), low-pressure CVD (LPCVD) or epitaxial growth, physical vapor deposition (PVD) such as sputtering or evaporation, or electroplating. The particular thickness of the one or more layers to be etched 102 will vary depending on the materials and particular devices being formed.

Depending on the particular layers to be etched, film thicknesses and photolithographic materials and process to be used, it may be desired to dispose over the layers 102 a hard mask layer 103 and/or a bottom antireflective coating (BARC) 104 over which a photoresist layer 106 is to be coated. Use of a hard mask layer may be desired, for example, with very thin resist layers, where the layers to be etched require a significant etching depth, and/or where the particular etchant has poor resist selectivity. Where a hard mask layer is used, the resist patterns to be formed can be transferred to the hard mask layer 103 which, in turn, can be used as a mask for etching the underlying layers 102. Suitable hard mask materials and formation methods are known in the art. Typical materials include, for example, tungsten, titanium, titanium nitride, titanium oxide, zirconium oxide, aluminum oxide, aluminum oxynitride, hafnium oxide, amorphous carbon, spin-on-carbon (SOC), silicon oxynitride and silicon nitride. The hard mask layer can include a single layer or a plurality of layers of different materials. The hard mask layer can be formed, for example, by CVD, PVD, or spin-coating techniques.

A bottom antireflective coating may be desirable where the substrate and/or underlying layers would otherwise reflect a significant amount of incident radiation during photoresist exposure such that the quality of the formed pattern would be adversely affected. Such coatings can improve depth-of-focus, exposure latitude, linewidth uniformity and CD control. Antireflective coatings are typically used where the resist is exposed to deep ultraviolet radiation (300 nm or less), for example, KrF (248 nm), ArF (193 nm) or EUV (13.5 nm) radiation. The antireflective coating can comprise a single layer or a plurality of different layers. Suitable antireflective materials and methods of formation are known in the art. Antireflective materials are commercially available, for example, those sold under the AR™ tradename by DuPont (Wilmington, Del. USA), such as AR™3 AR™ 40A and AR™124 antireflectant materials, DUV-30 Series and DUV-40 Series produced by Brewer Science, Inc., and ARC Series (e.g., ARC29A) produced by Nissan Chemical Industries, Ltd. may be used. Furthermore, an inorganic antireflection film can also be used as the antireflection film. For example, an antireflection film such as titanium, titanium dioxide, titanium nitride, chromium oxide, carbon and amorphous silicon may be used.

A photoresist layer 106 formed from a chemically amplified photosensitive composition is disposed on the substrate over the antireflective layer (if present). The chemically amplified photosensitive composition typically comprises, (a) a matrix polymer having acid labile groups of which solubility in an alkali developer increases and solubility in an organic solvent decreases under the action of an acid; (b) a compound capable of generating an acid upon irradiation with actinic rays or radiation, commonly referred to as a photoacid generator; (c) a solvent which can be used for dissolving respective components of the photoresist composition; and (d) optionally, other additives, wherein other additives include at least one of a resin having at least either a fluorine atom or a silicon atom, a basic compound, a surfactant, an onium carboxylate, dye, a plasticizer, a photosensitizer, a light absorbent, an alkali-soluble resin, a dissolution inhibitor, and a compound for accelerating dissolution in a developer.

The photoresist layer is disposed on the substrate over the antireflective layer 104 (if present). The photoresist composition can be applied to the substrate by spin-coating, dipping, roller-coating or other conventional coating technique. Of these, spin-coating is typical. For spin-coating, the solids content of the coating solution can be adjusted to provide a desired film thickness based upon the specific coating equipment utilized, the viscosity of the solution, the speed of the coating tool and the amount of time allowed for spinning. A typical thickness for the photoresist layer 106 is from about 500 to 3000 Å.

The photoresist layer 106 is typically next softbaked to minimize the solvent content in the layer, thereby forming a tack-free coating and improving adhesion of the layer to the substrate. The softbake can be conducted on a hotplate or in an oven, with a hotplate being typical. The softbake temperature and time will depend, for example, on the particular material of the photoresist and thickness. Typical softbakes are conducted at a temperature of from about 90 to 150° C., and a time of from about 30 to 90 seconds.

The photoresist layer 106 is next exposed to activating radiation 108 through a photomask 110 to create a difference in solubility between exposed and unexposed regions. References herein to exposing a photoresist composition to radiation that is activating for the composition indicates that the radiation is capable of forming a latent image in the photoresist composition. The photomask has optically transparent and optically opaque regions corresponding to regions of the resist layer to be exposed and unexposed, respectively, by the activating radiation. The exposure device for use in the present disclosure is not limited in the light source wavelength, but, for example, a KrF excimer laser wavelength (248 nm), an ArF excimer laser wavelength (193 nm), an F₂ excimer laser wavelength (157 nm) and an EUV light (13.5 nm) can be applied. In the step of performing exposure of the present disclosure, an immersion exposure method can be applied. The immersion exposure method is a technique for enhancing the resolving power, and according to this technique, exposure is performed by filling a high refractive-index liquid (hereinafter sometimes referred to as an “immersion liquid”) between the projection lens and the sample. The exposure energy is typically from about 10 to 80 mJ/cm², depending, for example, on the exposure tool and the components of the photosensitive composition.

Following exposure of the photoresist layer 106, a post-exposure bake (PEB) is typically performed. The PEB can be conducted, for example, on a hotplate or in an oven. Conditions for the PEB will depend, for example, on the particular photoresist composition and layer thickness. The PEB is typically conducted at a temperature of from about 80 to 150° C., and a time of from about 30 to 90 seconds. A latent image defined by the boundary between polarity-switched and unswitched regions (corresponding to exposed and unexposed regions, respectively) is thereby formed.

The photoresist layer 106 is next developed using a bio-based developer to remove the unexposed regions of the layer, leaving exposed regions forming a resist pattern 106′ having a plurality of features as shown in FIG. 1B. The features are not limited and can include, for example, a plurality of lines, pillars and/or contact hole patterns which allow for the formation of such patterns in the underlying layers to be patterned. As regards the negative development method, for example, a method of dipping a substrate in a bath filled with the developer for a fixed time (dip method), a method of raising the developer on a substrate surface by the effect of a surface tension and keeping it still for a fixed time, thereby performing the development (puddle method), a method of spraying the developer on a substrate surface (spray method), and a method of continuously ejecting the developer on a substrate rotating at a constant speed while scanning the developer ejecting nozzle at a constant rate (dynamic dispense method) may be applied.

After the step of performing negative development with the bio-based developer, a step of stopping the development by the replacement with another solvent may be practiced. A step of washing the resist film with a rinsing solution containing a bio-based organic solvent is preferably provided after the step of performing negative development. The washing treatment method is not particularly limited but, for example, a method of continuously ejecting the rinsing solution on a substrate rotating at a constant speed (rotary coating method), a method of dipping a substrate in a bath filled with the rinsing solution for a fixed time (dip method), and a method of spraying the rinsing solution of a substrate surface (spray method) may be applied.

Also, a treatment of removing the bio-based developer or bio-based rinsing solution adhering on the pattern by using a supercritical fluid may be performed after the development or rinsing treatment. Furthermore, after the development, the rinsing or the treatment with a supercritical fluid, a heat treatment may be performed for removing the solvent remaining in the pattern. The heating temperature is not particularly limited as long as a good resist pattern is obtained. In some embodiments, the heating temperature is from about 40 to 160° C. The heat treatment may be performed a plurality of times.

Using the resist pattern 106 as an etch mask, the BARC layer 104 is selectively etched to form BARC patterns 104′, exposing the underlying hardmask layer 103, as shown in FIG. 1C. The hardmask layer is next selectively etched, again using the resist pattern as an etch mask, resulting in patterned BARC and hardmask layer 103′, as shown in FIG. 1D. Suitable etching techniques and chemistries for etching the BARC layer and hardmask layer are known in the art and will depend, for example, on the particular materials of these layers. Dry-etching processes such as reactive ion etching are typical. The resist pattern 106 and patterned BARC layer 104′ are next removed from the substrate using known techniques, for example, oxygen plasma ashing. Using the hardmask pattern 103′ as an etch mask, the one or more layers 102 are then selectively etched. Suitable etching techniques and chemistries for etching the underlying layers 102 are known in the art. In some embodiments, dry-etching processes such as reactive ion etching being are used to etch the underlying layers 102. The patterned hardmask layer 103′ can next be removed from the substrate surface using known techniques, for example, a dry-etching process such as reactive ion etching or a wet strip. The resulting structure is a pattern of etched features 102′ as illustrated in FIG. 1E. In an alternative exemplary method, it may be desirable to pattern the layer 102 directly using the photoresist pattern 106 without the use of a hardmask layer 103. Whether direct patterning with the resist patterns can be employed will depend on factors such as the materials involved, resist selectivity, resist pattern thickness and pattern dimensions.

Example embodiments described herein include:

Embodiment 1: A composition comprising: an organic developer comprising at least 25 wt % bio-based n-butyl acetate wherein the bio-based n-butyl acetate comprises an amount of carbon-14 sufficient to produce a decay of at least 0.1 dpm/gC (disintegrations per minute per gram carbon); and wherein the organic developer comprises 5 ppb or less of metal element concentration of each of Na, K, Ca, Fe, Cu, Mg, Mn, Li, Al, Cr, Ni, and Zn.

Embodiment 2: The composition of embodiment 1, wherein the organic developer further comprises 1 ppb or less of an alkane or alkene having a carbon number of 22 or less; or 3 wt % or less bio-based n-butanol.

Embodiment 3: The composition of embodiment 1 or embodiment 2, wherein the organic developer comprises 3 ppb or less of metal element concentration of each of Na, K, Ca, Fe, Cu, Mg, Mn, Li, Al, Cr, Ni, and Zn; and optionally, one or both of 0.5 ppb or less of an alkane or alkene having a carbon number of 22 or less; and 1 wt % or less bio-based n-butanol, 0.1 wt % or less n-hexadecane, 0.1 wt % or less isopropanol, and 0.1 wt % or less ethyl acetate.

Embodiment 4: The composition of any of embodiments 1-3, wherein the organic developer comprises 1 ppb or less of metal element concentration of each of Na, K, Ca, Fe, Cu, Mg, Mn, Li, Al, Cr, Ni, and Zn; and optionally, one or both of 0.3 ppb or less of an alkane or alkene having a carbon number of 22 or less; and 1 wt % or less in total other bio-based solvents.

Embodiment 5: The composition of any of embodiments 1-4, wherein the organic developer comprises at least 90 wt % bio-based n-butyl acetate.

Embodiment 6: The composition of any of embodiments 1-4, wherein the organic developer comprises at least 95 wt % bio-based n-butyl acetate.

Embodiment 7: The composition of any of embodiments 1-6, wherein the organic developer further comprises 0.001 wt % to 5 wt % surfactant.

Embodiment 8: The composition of embodiment 7, wherein the surfactant comprises an ionic or nonionic fluorine-based or silicon-based surfactant.

Embodiment 9: The composition of any of embodiments 1-8, wherein the organic developer comprises at least 95 wt % bio-based n-butyl acetate; 0-2 wt % ionic or nonionic fluorine-based or silicon-based surfactant; 1 ppb or less of an alkane or alkene having a carbon number of 22 or less; 1 ppb or less of metal element concentration of each of Na, K, Ca, Fe, Cu, Mg, Mn, Li, Al, Cr, Ni, and Zn; and 1 wt % or less in total other bio-based solvents.

Embodiment 10: The composition of any of embodiments 1-9, wherein the organic developer further comprises 0.1 wt % to 10 wt % of a nitrogen-containing compound having the structure:

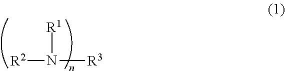

wherein R¹, R² and R³ individually represent a hydrogen atom, a hydroxyl group, a formyl group, an alkoxy group, an alkoxycarbonyl group, an optionally substituted C₁₋₃₀ alkyl group, an optionally substituted C₃₋₃₀ cycloalkyl or aryl group, or a group formed by two or more of these groups, and two of R¹, R² and R³ may bond to form a cyclic structure together with the nitrogen atom bonded thereto.

Embodiment 11: The composition of any of embodiments 1-10, wherein the bio-based n-butyl acetate comprises an amount of carbon-14 sufficient to produce a decay of at least 3.0 dpm/gC.

Embodiment 12: The composition of embodiment 11, wherein the bio-based n-butyl acetate comprises an amount of carbon-14 sufficient to produce a decay of at least 6.0 dpm/gC.

Embodiment 13: The composition of embodiment 11, wherein the bio-based n-butyl acetate comprises an amount of carbon-14 sufficient to produce a decay of at least 9.0 dpm/gC.

Embodiment 14: The composition of embodiment 11, wherein the bio-based n-butyl acetate comprises an amount of carbon-14 sufficient to produce a decay of at least 12.0 dpm/gC.

Embodiment 15: A pattern forming method comprising: providing a semiconductor substrate; forming a resist film comprising coating the semiconductor substrate with a resist composition having a solubility, wherein the solubility of the resist composition in an organic developer decreases upon irradiation with actinic rays or radiation; exposing the resist film with actinic rays or electromagnetic radiation; and developing the resist film with the organic developer, the organic developer comprising at least 25 wt % bio-based n-butyl acetate wherein the bio-based n-butyl acetate comprises an amount of carbon-14 sufficient to produce a decay of at least 0.1 dpm/gC.

Embodiment 16: The method of embodiment 15, wherein the solubility of the resist composition, after exposing the resist film with actinic rays or electromagnetic radiation, in the organic developer is 25 or less as described by a ratio mₛᵥ/mₛᵤ, wherein mₛᵥ is a mass of the solvent of the organic developer required to dissolve one unit of mass of resist composition, mₛᵤ.

Embodiment 17: The method of embodiment 15 or embodiment 16, further comprising forming an integrated circuit on the semiconductor substrate.

Embodiment 18: The method of embodiment 17, wherein the integrated circuit has a transistor density of 3×10⁷ transistors/mm².

Embodiment 19: The method of any of embodiments 15-18, wherein the organic developer comprises one or more of: 1 ppb or less of an alkane or alkene having a carbon number of 22 or less; 5 ppb or less of metal element concentration of each of Na, K, Ca, Fe, Cu, Mg, Mn, Li, Al, Cr, Ni, and Zn; and 3 wt % or less bio-based n-butanol.

Embodiment 20: The method of any of embodiments 15-19, wherein the organic developer comprises one or more of: 0.5 ppb or less of an alkane or alkene having a carbon number of 22 or less; 3 ppb or less of metal element concentration of each of Na, K, Ca, Fe, Cu, Mg, Mn, Li, Al, Cr, Ni, and Zn; and 1 wt % or less bio-based n-butanol, 0.1 wt % or less n-hexadecane, 0.1 wt % or less isopropanol, and 0.1 wt % or less ethyl acetate.

Embodiment 21: The method of any of embodiments 15-21, wherein the organic developer comprises one or more of: 0.3 ppb or less of an alkane or alkene having a carbon number of 22 or less; 2 ppb or less of metal element concentration of each of Na, K, Ca, Fe, Cu, Mg, Mn, Li, Al, Cr, Ni, and Zn; and 1 wt % or less in total other bio-based solvents.

Embodiment 22: The method of any of embodiments 15-21, wherein the organic developer comprises at least 90 wt % bio-based n-butyl acetate.

Embodiment 23: The method of any of embodiments 15-22, wherein the organic developer comprises at least 95 wt % bio-based n-butyl acetate.

Embodiment 24: The method of any of embodiments 15-23, wherein the organic developer further comprises 0.001 wt % to 5 wt % surfactant.

Embodiment 25: The method of embodiment 24, wherein the surfactant comprises an ionic or nonionic fluorine-based or silicon-based surfactant.

Embodiment 26: The method of any of embodiments 15-25, wherein the organic developer further comprises 0.1 wt % to 10 wt % of a nitrogen-containing compound having the structure:

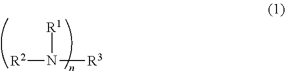

wherein R¹, R² and R³ individually represent a hydrogen atom, a hydroxyl group, a formyl group, an alkoxy group, an alkoxycarbonyl group, an optionally substituted C₁₋₃₀ alkyl group, an optionally substituted C₃₋₃₀ cycloalkyl or aryl group, or a group formed by two or more of these groups, and two of R¹, R² and R³ may bond to form a cyclic structure together with the nitrogen atom bonded thereto.

Embodiment 27: The method of any of embodiments 15-26, wherein the bio-based n-butyl acetate comprises an amount of carbon-14 sufficient to produce a decay of at least 3.0 dpm/gC.

Embodiment 28: The method of embodiments 27, wherein the bio-based n-butyl acetate comprises an amount of carbon-14 sufficient to produce a decay of at least 6.0 dpm/gC.

Embodiment 29: The method of embodiments 27, wherein the bio-based n-butyl acetate comprises an amount of carbon-14 sufficient to produce a decay of at least 9.0 dpm/gC.

Embodiment 30: The method of embodiments 27, wherein the bio-based n-butyl acetate comprises an amount of carbon-14 sufficient to produce a decay of at least 12.0 dpm/gC.

Embodiment 31: The method of any of embodiments 15-30, further comprising a step of rinsing the semiconductor substrate with a rinse solution after the developing step.

Embodiment 32: The method of embodiment 31, wherein the rinse solution comprises at least one bio-based organic solvent that comprises an amount of carbon-14 (C-14) sufficient to produce a decay of at least 0.1 dpm/gC and 5 ppb or less of a metal element concentration of each of Na, K, Ca, Fe, Cu, Mg, Mn, Li, Al, Cr, Ni, and, Zn.

Embodiment 33: The method of embodiment 31 or embodiment 32, wherein the at least one bio-based organic solvent is selected from the group consisting of one or more of a hydrocarbon-based solvent, a ketone-based solvent, an ester-based solvent, an alcohol-based solvent, an amide-based solvent, an ether-based solvent, and combinations thereof.

Embodiment 34: The method of any of embodiments 31-33, wherein the at least one bio-based organic solvent is selected from the group consisting of 1-hexanol, methyl isobutyl carbinol, 2-hexanol, 1-heptanol, 2-heptanol, and combinations thereof.

Embodiment 35: The method of any of embodiments 31-34, wherein the at least one bio-based organic solvent comprises an amount of carbon-14 sufficient to produce a decay of at least 3.0 dpm/gC.

Embodiment 36: The method of embodiment 35, wherein the at least one bio-based organic solvent comprises an amount of carbon-14 sufficient to produce a decay of at least 6.0 dpm/gC.

Embodiment 37: The method of embodiment 35, wherein the at least one bio-based organic solvent comprises an amount of carbon-14 sufficient to produce a decay of at least 9.0 dpm/gC.

Embodiment 38: The method of embodiment 35, wherein the at least one bio-based organic solvent comprises an amount of carbon-14 sufficient to produce a decay of at least 12.0 dpm/gC.

Embodiment 39: A rinse composition comprising: at least 25 wt % of at least one bio-based organic rinse solvent selected from the group consisting of one or more of a hydrocarbon-based solvent, a ketone-based solvent, an ester-based solvent, an alcohol-based solvent, an amide-based solvent, an ether-based solvent, and combinations thereof; wherein the bio-based organic rinse solvent comprises an amount of carbon-14 sufficient to produce a decay of at least 0.1 dpm/gC (disintegrations per minute per gram carbon); and wherein the rinse composition comprises 5 ppb or less of metal element concentration of each of Na, K, Ca, Fe, Cu, Mg, Mn, Li, Al, Cr, Ni, and Zn.

Embodiment 40: The rinse composition of embodiment 39, wherein the rinse composition further comprises 1 ppb or less of an alkane or alkene having a carbon number of 22 or less; or 3 wt % or less bio-based methyl isobutyl ketone.

Embodiment 41: The rinse composition of embodiment 39 or embodiment 40, wherein the rinse composition comprises 3 ppb or less of metal element concentration of each of Na, K, Ca, Fe, Cu, Mg, Mn, Li, Al, Cr, Ni, and Zn; and optionally, one or both of: 0.5 ppb or less of an alkane or alkene having a carbon number of 22 or less; and 1 wt % or less bio-based methyl isobutyl ketone, 0.1 wt % or less n-hexadecane, 0.1 wt % or less diisobutyl ketone, and 0.1 wt % or less methyl isoamyl ketone.

Embodiment 42: The rinse composition of any of embodiments 39-41, wherein the rinse composition comprises 2 ppb or less of metal element concentration of each of Na, K, Ca, Fe, Cu, Mg, Mn, Li, Al, Cr, Ni, and Zn; and optionally, one or both of: 0.3 ppb or less of an alkane or alkene having a carbon number of 22 or less; and 1 wt % or less in total other bio-based solvents.

Embodiment 43: The rinse composition of any of embodiments 39-42, wherein the at least one bio-based organic solvent is selected from the group consisting of one or more of 1-hexanol, methyl isobutyl carbinol, 2-hexanol, 1-heptanol, 2-heptanol, methyl isoamyl carbinol, diisobutyl carbinol, and combinations thereof.

Embodiment 44: The rinse composition of any of embodiments 39-43, wherein the at least one bio-based organic solvent is at least 90 wt % of one or more of bio-based: 1-hexanol, methyl isobutyl carbinol, 2-hexanol, 1-heptanol, 2-heptanol, methyl isoamyl carbinol and diisobutyl carbinol.

Embodiment 45: The rinse composition of any of embodiments 39-44, wherein the at least one bio-based organic solvent is at least 95 wt % of one or more of bio-based: 1-hexanol, methyl isobutyl carbinol, 2-hexanol, 1-heptanol, 2-heptanol, methyl isoamyl carbinol and diisobutyl carbinol.

Embodiment 46: The composition of any of embodiments 39-45, wherein the at least one bio-based organic solvent comprises an amount of carbon-14 sufficient to produce a decay of at least 3.0 dpm/gC.

Embodiment 47: The composition of embodiment 46, wherein the at least one bio-based organic solvent comprises an amount of carbon-14 sufficient to produce a decay of at least 6.0 dpm/gC.

Embodiment 48: The composition of embodiment 46, wherein the at least one bio-based organic solvent comprises an amount of carbon-14 sufficient to produce a decay of at least 9.0 dpm/gC.

Embodiment 49: The composition of embodiment 46, wherein the at least one bio-based organic solvent comprises an amount of carbon-14 sufficient to produce a decay of at least 12.0 dpm/gC.

Embodiment 50: A photoresist composition comprising a polymer binder, or a mixture of polymer binders, which become alkali-soluble by the action of an acid to remove protecting acid sensitive groups on the polymer binder, at least one photo acid generator (PAG), which upon exposure to a source of high energy, decomposes and generates a photoacid strong enough to remove the protecting acid sensitive groups on the polymer binder, at least one bio-based organic solvent; and optionally at least one base as a quencher; and wherein the bio-based organic solvent comprises at least 25 wt % bio-based n-butyl acetate wherein the bio-based n-butyl acetate comprises an amount of carbon-14 sufficient to produce a decay of at least 0.1 dpm/gC; and wherein the organic solvent comprises 5 ppb or less of metal element concentration of each of Na, K, Ca, Fe, Cu, Mg, Mn, Li, Al, Cr, Ni, and Zn.

Embodiment 51: The composition of embodiment 50, wherein the bio-based organic solvent further comprises 1 ppm or less of an alkane or alkene having a carbon number of 22 or less; or 3 wt % or less bio-based n-butanol.

Embodiment 52: The composition of embodiment 50 or embodiment 51, wherein the bio-based organic solvent comprises 3 ppm or less of metal element concentration of each of Na, K, Ca, Fe, Cu, Mg, Mn, Li, Al, Cr, Ni, and Zn; and optionally, one or both of 0.5 ppm or less of an alkane or alkene having a carbon number of 22 or less; and 1 wt % or less bio-based n-butanol, 0.1 wt % or less n-hexadecane, 0.1 wt % or less isopropanol, and 0.1 wt % or less ethyl acetate.

Embodiment 53: The composition of any of embodiments 50-53, wherein the bio-based organic solvent comprises 2 ppm or less of metal element concentration of each of Na, K, Ca, Fe, Cu, Mg, Mn, Li, Al, Cr, Ni, and Zn; and optionally, one or both of 0.3 ppm or less of an alkane or alkene having a carbon number of 22 or less; and 1 wt % or less in total other bio-based solvents.

Embodiment 54: The composition of any of embodiments 50-54, wherein the bio-based organic solvent comprises at least 90 wt % bio-based n-butyl acetate.

Embodiment 55: The composition of any of embodiments 50-55, wherein the bio-based organic solvent comprises at least 95 wt % bio-based n-butyl acetate.

Embodiment 56: The composition of any of embodiments 50-56, wherein the bio-based organic solvent further comprises 0.001 wt % to 5 wt % surfactant.

Embodiment 57: The composition of embodiment 56, wherein the surfactant comprises an ionic or nonionic fluorine-based or silicon-based surfactant.

Embodiment 58: The composition of any of embodiments 50-57, wherein the bio-based organic solvent comprises at least 95 wt % bio-based n-butyl acetate; 0.3 ppm or less of an alkane or alkene having a carbon number of 22 or less; 2 ppm or less of metal element concentration of each of Na, K, Ca, Fe, Cu, Mg, Mn, Li, Al, Cr, Ni, and Zn; and 1 wt % or less in total other bio-based solvents.

### EXAMPLES

### Example 1. Formation of Bio-Based Developer n-Butyl Acetate (NBA)

Bio-based NBA is produced in a bioreactor using fermentation of glucose or glycerol as described in 12 Nat. Commun. 4368 (2021). The fermentation is performed in a serum bottle in a two-phase system with the extractant n-hexadecane added into the fermentation with a ratio of 1:1 (volume of the extractant vs. volume of fermentation broth) for in situ ester extraction. The organic layer containing NBA and hexadecane is removed and subjected to a distillation to isolate the purified NBA. Metals are removed by treatment with ion exchange beads and/or passing through a purifier, and particles are removed by passing the solvent through a PTFE filter having a pore size of 0.05 μm. Further purification steps are done to reduce the low molecular weight organic compound content and metal concentrations. The final bio-based NBA negative developer comprises 1 ppb or less of alkane or alkenes having a carbon number of 22 or less measured by gas chromatography mass spectrometry GCMS-QP2010 manufactured by Shimadzu Corporation connected to a pyrolysis apparatus PY2020D manufactured by Frontier Lab; 5 ppb or less of metal element concentration of each of Na, K, Ca, Fe, Cu, Mg, Mn, Li, Al, Cr, Ni, and Zn as measured by inductively coupled plasma mass spectrometer, Agilent 7500cs (ICP-MS equipment) manufactured by Agilent Technologies, Inc.); and 3 wt % or less bio-based n-butanol as measured via Liquid scintillation-counter method (LSC).

### Example 2. Formation of Bio-Based Developer n-Butyl Acetate (NBA)

Bio-based NBA is produced in a bioreactor using fermentation with a FadM homolog from Providencia sneebia as described in 61 Metabolic Engineering 335-343 (2020). The product is purified as described above in Example 1. The end product is isolated and analyzed. Analysis shows that the bio-based NBA developer comprises 0.5 ppb or less of an alkane or alkene having a carbon number of 22 or less; 1 ppb or less of metal element concentration of each of Na, K, Ca, Fe, Cu, Mg, Mn, Li, Al, Cr, Ni, and Zn; and 0.1 wt % or less bio-based n-butanol, 0.1 wt % or less n-hexadecane, 0.1 wt % or less isopropanol, and 0.1 wt % or less ethyl acetate.

### Example 3. Formation of Bio-Based Methyl Isobutyl Carbinol

A two-step biobased process, described in U.S. Pat. Publ. No. 2014/0329275, converts glucose into methyl isobutyl ketone (MIBK). The process utilizes a modified microbe that converts glucose into isovaleric acid and isocaproate, which is then converted to the corresponding ketone. The ketone is then reduced to the corresponding alcohol methyl isobutyl carbinol (MIBC). The resulting MIBC is processed to the desired purity by distillation, metals removal using ion exchange or a purifier to produce 3 ppb or less of metal element concentration of each of Na, K, Ca, Fe, Cu, Mg, Mn, Li, Al, Cr, Ni, and Zn, and PTFE filtration to remove particles (20 particles/mL or less determined by, for example, a KLA SURFSCAN® SP7 unpatterned wafer inspection system).

### Example 4. Formation of Bio-Based Hexanol

Bio-based hexanol is produced by fermentation of syngas using Clostridium carboxidivorans P7 according to the methods described in 10 Front. Bioeng. Biotechnol., art. 850370 (2022). The resulting hexanol is processed to the desired purity by distillation, metals removal using ion exchange or a purifier, and filtration to remove particles.

### Example 5. Formation of Bio-Based Heptanol

Bio-based 1-heptanol is derived from a renewable castor oil source is supplied by Arkema. The heptanol is processed to the desired purity (97 wt %) by distillation, metals removal using ion exchange or a purifier to produce 1 ppb or less of metal element concentration of each of Na, K, Ca, Fe, Cu, Mg, Mn, Li, Al, Cr, Ni, and Zn, and PTFE filtration to remove particles (20 particles/mL or less determined by, for example, a KLA SURFSCAN® SP7 unpatterned wafer inspection system).

### Example 5. Identification of Developer and Rinse as Bio-Based

The following samples are measured, in a blind test fashion, to determine the presence of C-14 content by liquid scintillation counting. The results are shown in Table 2. As shown in Table 2, samples totally derived from petroleum (Comparatives A and B) contain a negligible amount of C-14 as measured in dpm/gC, indicating that about zero percent of the sample is made from bio-based materials. In contrast, samples that contain materials known to be derived from a bio-based material show higher levels of C-14 as measured in dpm/gC.

TABLE 2

| ID | Sample Description | (dpm/gC) |
|---|---|---|
| Comparative A | NBA (totally derived from petroleum) | <0.01 |
| Example 1 | Bio-based NBA | 13.5 ± 0.1 |
| Comparative B | MIBC (totally derived from petroleum) | <0.01 |
| Example 3 | Bio-based MIBC | 13.2 ± 0.2 |
| Example 4 | Bio-based 1-hexanol | 13.4 ± 0.1 |
| Example 5 | Bio-based 1-heptanol | 13.3 ± 0.2 |

### Example 6. Photolithography Process for Making an NTD Pattern, Developing, and Rinsing

A 200 mm silicon wafer is coated with ART™3-600 organic bottom anti-reflective coating (BARC) material (DuPont) and baked at 205° C. for 60 seconds to a thickness of 600 Å on a Tokyo Electron Ltd. (TEL) CLEAN TRACK™ Act 8 coating tool. UV™217G-0.25 polyhydroxystyrene-based photoresist (DuPont) is coated over the BARC layer and the wafers are softbaked at 130° C. for 60 seconds to a target thickness of 3550 Å on the coating tool. The coated wafers are exposed to KrF (248 nm) radiation on a Canon FPA-5000 ES4 DUV scanner with NA=0.68, conventional illumination (Sigma, 0.75) using a binary reticle with a 140 nm dense (1:1 line-space) trench patterns. The wafers are post-exposure baked at 125° C. for 60 seconds, developed with bio-based n-butyl acetate for 45 seconds, rinsed with bio-based methyl isobutyl carbinol, and spun dry on a Tokyo Electron Ltd. (TEL) CLEAN TRACK™ Act 8 coating tool. The resist pattern is then examined using a scanning electron microscope, revealing the expected line-space patterns.

EPIC™ 3013 ArF photoresist (Rohm and Haas Electronic Materials LLC) is spin-coated on an organic bottom antireflective coating (BARC AR™124 23 nm/AR™26N 77 nm (Rohm and Haas Electronic Materials LLC)) over a 12 inch silicon wafer and softbaked at 110° C. for 60 seconds, to a thickness of 900 Å. OPTICOAT™ OC2000 topcoat material (Rohm and Haas Electronic Materials LLC) is coated on the resist to form an immersion topcoat layer. The coated wafer is exposed with an ASML ArF 1900i immersion scanner with NA=1.35, Dipole 35Y illumination (0.9/0.635 sigma), plus x polarization, and post-exposure baked (PEB) at 100° C. for 60 seconds. The coated wafer is developed with bio-based n-butyl acetate from Example 1 for 45 seconds, rinsed with bio-based methyl isobutyl carbinol from Example 3, and spun dry on a Tokyo Electron Ltd. (TEL) CLEAN TRACK™ coating tool.

### Example 7. Photolithography Process for Making an NTD Pattern, Developing, and Rinsing

The procedure of Example 6 was repeated with the following modification: the coated wafer is developed with bio-based n-butyl acetate from Example 1 for 45 seconds, rinsed with bio-based 1-hexanol from Example 4, and spun dry on a Tokyo Electron Ltd. (TEL) CLEAN TRACK™ coating tool.

### Example 8. Photolithography Process for Making an NTD Pattern, Developing, and Rinsing

The procedure of Example 6 was repeated with the following modification: the coated wafer is developed with bio-based n-butyl acetate from Example 1 for 45 seconds, rinsed with bio-based 1-heptanol from Example 4, and spun dry on a Tokyo Electron Ltd. (TEL) CLEAN TRACK™ coating tool.

1) A pattern forming method for forming a semiconductor device, the method comprising:
a) providing a semiconductor substrate;
b) providing a resist composition comprising a film-forming resist material, a photoacid generator, and a carrier solvent that is optionally bio-based;
c) forming a resist film comprising coating the semiconductor substrate with the resist composition and removing the carrier solvent, wherein the resist film has a solubility in an organic developer that decreases upon irradiation with actinic rays or radiation;
d) exposing the resist film to actinic rays or electromagnetic radiation; and
e) developing the resist film with a bio-based organic developer, the bio-based organic developer comprising:
i) at least 25 wt % of a bio-based n-butyl acetate, wherein the bio-based n-butyl acetate comprises an amount of carbon-14 sufficient to produce a decay of at least 0.1 dpm/gC;
ii) less than 20 particles having a particle size of 0.15 μm or less per milliliter of bio-based organic developer;
iii) 1 ppb or less of an alkane or alkene having a carbon number of 22 or less;
iv) 5 ppb or less of metal concentration of each of Na, K, Ca, Fe, Cu, Mg, Mn, Li, Al, Cr, Ni, and Zn; and
v) 1 wt % or less of bio-based n-butanol, 0.1 wt % or less of bio-based n-hexadecane, 0.1 wt % or less of bio-based isopropanol, or 0.1 wt % or less of bio-based ethyl acetate.

2) The method of claim 1, wherein the solubility of the resist composition, after exposing the resist film with actinic rays or electromagnetic radiation, in the organic developer is 25 or less as described by a ratio mₛᵥ/mₛᵤ, wherein mₛᵥ is a mass of the solvent of the organic developer required to dissolve one unit of mass of resist composition, mₛᵤ.

3) The method of claim 1, wherein the bio-based n-butyl acetate is synthesized by a process that produces the bio-based n-butyl acetate in a mass fraction of 94.3% or greater.

4) The method of claim 1, wherein the semiconductor substrate is silicon.

5) The method of claim 1, wherein the developer comprises less than 10 particles having a particle size of 0.15 μm or less per milliliter of bio-based organic developer.

6) The method of claim 1, wherein the developer comprises 1 ppb or less of each of Na, K, Ca, Fe, Cu, Mg, Mn, Li, Al, Cr, Ni, and Zn and 0.5 ppb or less of an alkane or alkene having a carbon number of 22 or less.

7) The method of claim 1, wherein the carrier solvent comprises a bio-based carrier solvent component comprising at least 0.1 dpm/gC (disintegrations per minute per gram carbon) of carbon-14 (C-14), and optionally, one or more of the following: a basic compound, a surfactant, or photo-decomposable quencher.

8) The method of claim 1, further comprising forming an integrated circuit on the semiconductor substrate, wherein the integrated circuit has a transistor density of 3×10⁷ transistors/mm².

9) The method of claim 1, wherein the developer comprises at least 90 wt % of a bio-based n-butyl acetate.

10) The method of claim 1, wherein the developer comprises at least 95 wt % of a bio-based n-butyl acetate.

11) The method of claim 1, wherein the organic developer further comprises 0.001 wt % to 5 wt % surfactant.

12) The method of claim 11, wherein the surfactant comprises an ionic or nonionic fluorine-based or silicon-based surfactant.

13) The method of claim 1, wherein the bio-based n-butyl acetate comprises an amount of carbon-14 sufficient to produce a decay of at least 3.0 dpm/gC.

14) The method of claim 13, wherein the bio-based n-butyl acetate comprises an amount of carbon-14 sufficient to produce a decay of at least 9.0 dpm/gC.

15) The method of claim 14, wherein the bio-based n-butyl acetate comprises an amount of carbon-14 sufficient to produce a decay of at least 12.0 dpm/gC.

16) The method of claim 1, further comprising a step of rinsing the semiconductor substrate with a rinse solution after the developing step.

17) The method of claim 16, wherein the rinse solution comprises at least one bio-based organic rinse solvent that comprises an amount of carbon-14 (C-14) sufficient to produce a decay of at least 0.1 dpm/gC (disintegrations per minute per gram carbon) and 5 ppb or less of a metal element concentration of each of Na, K, Ca, Fe, Cu, Mg, Mn, Li, Al, Cr, Ni, and, Zn.

18) The method of claim 17, wherein the at least one bio-based organic rinse solvent is selected from the group consisting of one or more of a hydrocarbon-based solvent, a ketone-based solvent, an ester-based solvent, an alcohol-based solvent, an amide-based solvent, an ether-based solvent, and combinations thereof.

19) The method of claim 18, wherein the at least one bio-based organic rinse solvent is selected from the group consisting of 1-hexanol, methyl isobutyl carbinol, 2-hexanol, 1-heptanol, 2-heptanol, and combinations thereof.

20) The method of claim 17, wherein the at least one bio-based organic rinse solvent comprises an amount of carbon-14 sufficient to produce a decay of at least 9.0 dpm/gC.
